(19) United States
(12) Patent Application Publication
(10) Pub. No.: US 2026/0214803 A1
(43) Pub. Date: Jul. 23, 2026

(54) PRINTED CIRCUIT BOARD RESONATOR AND METHOD OF FORMING THE SAME

(71) Applicant: Nanyang Technological University, Singapore (SG)

(72) Inventors: Kerui Li, Singapore (SG); Shu Yuen Ron Hui, Singapore (SG)

(21) Appl. No.: 19/138,051

(22) PCT Filed: Jan. 10, 2024
(86) PCT No.: PCT/SG2024/050017

§ 371 Date: Jun. 11, 2025

(30) Foreign Application Priority Data
Jan. 13, 2023 (SG) 10202300104Y

(51) Int. Cl. H05K 1/16; H01F 27/28; H01F 27/32; H01F 41/04; H02J 50/00; H02J 50/12; H05K 1/11; H05K 1/14; H05K 3/36

(52) U.S. Cl. CPC H05K 1/165; H01F 27/2804; H01F 27/2871; H01F 27/323; H01F 41/041; H02J 50/005; H02J 50/12; H05K 1/115; H05K 1/144; H05K 3/368; H01F 2027/2809

(57) ABSTRACT

A printed circuit board (PCB) resonator. The printed circuit board (PCB) resonator may include a first printed circuit board (PCB) including a first printed circuit board (PCB) substrate having only one side printed with a first coil. The printed circuit board (PCB) resonator may also include a second printed circuit board (PCB) spaced apart from the first printed circuit board (PCB), the second printed circuit board (PCB) including a second printed circuit board (PCB) substrate having only one side printed with a second coil. The first printed circuit board (PCB) substrate may include slots between portions of the first printed circuit board (PCB) substrate in contact with the first coil. The second printed circuit board (PCB) substrate may include slots between portions of the second printed circuit board (PCB) substrate in contact with the second coil.

### CROSS-REFERENCE TO RELATED APPLICATION

This application claims the benefit of priority of Singapore Application No. 10202300104Y filed Jan. 13, 2023, the contents of it being hereby incorporated by reference in its entirety for all purposes.

### TECHNICAL FIELD

Various embodiments of this disclosure may relate to a printed circuit board resonator. Various embodiments of this disclosure may relate to a method of forming a printed circuit board resonator.

### BACKGROUND

With the improvement of power electronics such as power metal oxide semiconductor field effect transistors (MOSFETs) in the 1980s, the switching frequency of switched mode power supplies could be increased from tens to hundreds of kilo-Hertz (kHz) to reduce the size of magnetics (such as isolation transformers) and increase power density. In 1998, it was demonstrated that the magnetic cores in isolation transformers can be eliminated with the use of coreless printed circuit board (PCB) transformers for both power and signal transfers when the operating frequency exceeds a few hundred kilo-Hertz. Removal of magnetic cores has the advantages of not only reducing the cost and size of magnetic cores but also alleviating frequency limitations and power losses of the magnetic cores. For these reasons, coreless PCB transformers could be operated beyond the Megahertz (MHz) frequency range over 20 years ago. With such advantages, coreless PCB transformers are attractive to power integrated circuit companies, and have been adopted in a family of industrial gate drive circuits for both individual power switches and inverter bridges since early 2000s. There is a series of related patents relating to operating coreless PCB transformers. Besides using PCB technology, the coreless planar transformer can, in principle, be manufactured using semiconductor technology, if the resistance of the coils can be kept to an acceptable level.

In recent years, research works on coreless PCB winding structures relating to medium-voltage and high-voltage gate drives, isolation transformers for multi mega-Hertz power supplies and domino resonators for wireless power transfer (WPT) applications have appeared. The PCB winding structures are particularly important for domino WPT systems in high-voltage (HV) insulation rod applications in HV transmission towers. Power companies have confirmed that manual windings and discrete capacitors are not suitable for such HV applications because of HV discharge between metallic terminals in discrete capacitors. PCB resonator structures have distributed inductance and capacitance, and can therefore avoid internal HV discharge. For domino WPT applications, a PCB resonator winding design optimized by the partial-element equivalent-circuit (PEEC) method has previously been reported. However, existing PCB resonator structures, when manufactured to the size for embedment inside standard insulation discs of commercial insulation rods, have limitations on operating frequency range and relatively low quality (Q) factor and energy efficiency, due to the dimensions of the PCB. In addition, these structures are restricted to parallel resonant configurations.

### SUMMARY

Various embodiments may provide a printed circuit board (PCB) resonator. The printed circuit board (PCB) resonator may include a first printed circuit board (PCB) including a first printed circuit board (PCB) substrate having only one side printed with a first coil. The printed circuit board (PCB) resonator may also include a second printed circuit board (PCB) spaced apart from the first printed circuit board (PCB), the second printed circuit board (PCB) including a second printed circuit board (PCB) substrate having only one side printed with a second coil. The first printed circuit board (PCB) substrate may include slots between portions of the first printed circuit board (PCB) substrate in contact with the first coil. The second printed circuit board (PCB) substrate may include slots between portions of the second printed circuit board (PCB) substrate in contact with the second coil.

Various embodiments may provide a wireless power transfer (WPT) system including one or more printed circuit board (PCB) resonators as described herein.

Various embodiments may provide a method of forming a printed circuit board (PCB) resonator. The method may include forming a first printed circuit board (PCB) including a first printed circuit board (PCB) substrate having only one side printed with a first coil. The method may also include forming a second printed circuit board (PCB) spaced apart from the first printed circuit board (PCB), the second printed circuit board (PCB) including a second printed circuit board (PCB) substrate having only one side printed with a second coil. The first printed circuit board (PCB) substrate may include slots between portions of the first printed circuit board (PCB) substrate in contact with the first coil. The second printed circuit board (PCB) substrate may include slots between portions of the second printed circuit board (PCB) substrate in contact with the second coil.

Various embodiments may provide a method of forming a wireless power transfer (WPT) system. The method may include forming one or more printed circuit board (PCB) resonators as described herein.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows a general illustration of a printed circuit board (PCB) resonator according to various embodiments.

FIG. 2 shows a general illustration of a method of forming a printed circuit board (PCB) resonator according to various embodiments.

FIG. 3A is a schematic showing the design variables for copper traces of a printed circuit broad (PCB) winding or coil according to various embodiments.

FIG. 3B is a flowchart of the optimization process according to various embodiments.

FIG. 4 is a table comparing the relative permittivity (Er), loss tangent, and unit costs of a common printed circuit board (PCB), a high frequency printed circuit board (PCB), and air.

FIG. 5A is a schematic showing an exploded view of a conventional printed circuit board (PCB) resonator.

FIG. 5B is a schematic showing a front view and a back view of the conventional printed circuit board (PCB) resonator shown in FIG. 5A.

FIG. 6A is a schematic showing an exploded view of a printed circuit board (PCB) resonator (Design-1) according to various embodiments.

FIG. 6B is a schematic showing a front view and a back view of the printed circuit board (PCB) resonator shown in FIG. 6A according to various embodiments.

FIG. 7A is a schematic showing an exploded view of a printed circuit board (PCB) resonator (Design-2) according to various embodiments.

FIG. 7B is a schematic showing a front view and a back view of the printed circuit board (PCB) resonator shown in FIG. 7A according to various embodiments.

FIG. 8 is a table summarizing the conventional printed circuit board (PCB) resonator as well as Design-1 and Design-2 printed circuit board (PCB) resonators according to various embodiments.

FIG. 9 shows (a) a second-order circuit according to various embodiments; and (b) equivalent circuit for a wireless power transfer (WPT) system with secondary parallel resonant circuit according to various embodiments.

FIG. 10 shows (a) a third-order circuit according to various embodiments; and (b) equivalent circuit for a wireless power transfer (WPT) system with secondary parallel resonant circuit for representing printed circuit board (PCB) resonators according to various embodiments.

FIG. 11A is a plot of impedance (in ohms or (2) as a function of frequency (in Hertz or Hz) illustrating the measured and theoretical impedance curves of the conventional printed circuit board (PCB) resonator.

FIG. 11B is a plot of impedance (in ohms or (2) as a function of frequency (in Hertz or Hz) illustrating the measured and theoretical impedance curves of the Design-1 printed circuit board (PCB) resonator according to various embodiments.

FIG. 11C is a plot of impedance (in ohms or (2) as a function of frequency (in Hertz or Hz) illustrating the measured and theoretical impedance curves of the Design-2 printed circuit board (PCB) resonator according to various embodiments.

FIG. 12 is a table comparing parameters of the conventional printed circuit board (PCB) resonator, as well as Design-1 printed circuit board (PCB) and Design-2 printed circuit board (PCB) resonators according to various embodiments.

FIG. 13A shows an image of a wireless power transfer system including four conventional printed circuit board (PCB) resonators.

FIG. 13B shows an image of a wireless power transfer system including four Design-1 printed circuit board (PCB) resonators according to various embodiments.

FIG. 13C shows an image of a wireless power transfer system including four Design-2 printed circuit board (PCB) resonators according to various embodiments.

FIG. 14 shows an equivalent circuit model of the 4-resonators domino wireless power transfer (WPT) system according to various embodiments.

FIG. 15 is a table showing the resulted mutual inductance of the 4-resonators domino wireless power transfer (WPT) systems of conventional printed circuit board (PCB) resonators as well as Design-1 and Design-2 resonators according to various embodiments.

FIG. 16A is a plot of impedance (in ohms or (2) as a function of frequency (in Hertz or Hz) illustrating the input impedance of the 4-resonators domino wireless power transfer (WPT) system of conventional printed circuit board (PCB) resonators.

FIG. 16B is a plot of phase (in degrees or °) as a function of frequency (in Hertz or Hz) illustrating the phase response of the 4-resonators domino wireless power transfer (WPT) system of conventional printed circuit board (PCB) resonators.

FIG. 17A is a plot of impedance (in ohms or (2) as a function of frequency (in Hertz or Hz) illustrating the input impedance of the 4-resonators domino wireless power transfer (WPT) system of Design-1 printed circuit board (PCB) resonators according to various embodiments.

FIG. 17B is a plot of phase (in degrees or °) as a function of frequency (in Hertz or Hz) illustrating the phase response of the 4-resonators domino wireless power transfer (WPT) system of Design-1 printed circuit board (PCB) resonators according to various embodiments.

FIG. 18A is a plot of impedance (in ohms or (2) as a function of frequency (in Hertz or Hz) illustrating the input impedance of the 4-resonators domino wireless power transfer (WPT) system of Design-2 printed circuit board (PCB) resonators according to various embodiments.

FIG. 18B is a plot of phase (in degrees or °) as a function of frequency (in Hertz or Hz) illustrating the phase response of the 4-resonators domino wireless power transfer (WPT) system of Design-2 printed circuit board (PCB) resonators according to various embodiments.

FIG. 19A shows a plot of voltage (in volts or V) as a function of time (in seconds or s) illustrating the input voltage vᵢₙ waveform of the 4-resonators domino wireless power transfer (WPT) system of conventional printed circuit board (PCB) resonators.

FIG. 19B shows a plot of current (in amperes or A) as a function of time (in seconds or s) illustrating the input current iᵢₙ waveform of the 4-resonators domino wireless power transfer (WPT) system of conventional printed circuit board (PCB) resonators.

FIG. 19C shows a plot of voltage (in volts or V) as a function of time (in seconds or s) illustrating the output voltage vₒ waveform of the 4-resonators domino wireless power transfer (WPT) system of conventional printed circuit board (PCB) resonators.

FIG. 19D shows a plot of current (in amperes or A) as a function of time (in seconds or s) illustrating the output current iₒ waveform of the 4-resonators domino wireless power transfer (WPT) system of conventional printed circuit board (PCB) resonators.

FIG. 20A shows a plot of voltage (in volts or V) as a function of time (in seconds or s) illustrating the input voltage vᵢₙ waveform of the 4-resonators domino wireless power transfer (WPT) system of Design-1 printed circuit board (PCB) resonators according to various embodiments.

FIG. 20B shows a plot of current (in amperes or A) as a function of time (in seconds or s) illustrating the input current iᵢₙ waveform of the 4-resonators domino wireless power transfer (WPT) system of Design-1 printed circuit board (PCB) resonators according to various embodiments.

FIG. 20C shows a plot of voltage (in volts or V) as a function of time (in seconds or s) illustrating the output voltage vₒ waveform of the 4-resonators domino wireless power transfer (WPT) system of Design-1 printed circuit board (PCB) resonators according to various embodiments.

FIG. 20D shows a plot of current (in amperes or A) as a function of time (in seconds or s) illustrating the output current iₒ waveform of the 4-resonators domino wireless power transfer (WPT) system of Design-1 printed circuit board (PCB) resonators according to various embodiments.

FIG. 21A shows a plot of voltage (in volts or V) as a function of time (in seconds or s) illustrating the input voltage vᵢₙ waveform of the 4-resonators domino wireless power transfer (WPT) system of Design-2 printed circuit board (PCB) resonators according to various embodiments.

FIG. 21B shows a plot of current (in amperes or A) as a function of time (in seconds or s) illustrating the input current iᵢₙ waveform of the 4-resonators domino wireless power transfer (WPT) system of Design-2 printed circuit board (PCB) resonators according to various embodiments.

FIG. 21C shows a plot of voltage (in volts or V) as a function of time (in seconds or s) illustrating the output voltage vₒ waveform of the 4-resonators domino wireless power transfer (WPT) system of Design-2 printed circuit board (PCB) resonators according to various embodiments.

FIG. 21D shows a plot of current (in amperes or A) as a function of time (in seconds or s) illustrating the output current iₒ waveform of the 4-resonators domino wireless power transfer (WPT) system of Design-2 printed circuit board (PCB) resonators according to various embodiments.

FIG. 22A is a plot of efficiency as a function of frequency (in Hertz or Hz) and load resistance (in ohms or (2) illustrating the efficiency curve of the 4-resonators domino wireless power transfer (WPT) system of conventional printed circuit board (PCB) resonators.

FIG. 22B shows the time-domain waveforms of the 4-resonators domino wireless power transfer (WPT) system of conventional printed circuit board (PCB) resonators.

FIG. 23A is a plot of efficiency as a function of frequency (in Hertz or Hz) and load resistance (in ohms or (2) illustrating the efficiency curve of the 4-resonators domino wireless power transfer (WPT) system of Design-1 printed circuit board (PCB) resonators according to various embodiments.

FIG. 23B shows the time-domain waveforms of the 4-resonators domino wireless power transfer (WPT) system of Design-1 printed circuit board (PCB) resonators according to various embodiments.

FIG. 24A is a plot of efficiency as a function of frequency (in Hertz or Hz) and load resistance (in ohms or (2) illustrating the efficiency curve of the 4-resonators domino wireless power transfer (WPT) system of Design-2 printed circuit board (PCB) resonators according to various embodiments.

FIG. 24B shows the time-domain waveforms of the 4-resonators domino wireless power transfer (WPT) system of Design-2 printed circuit board (PCB) resonators according to various embodiments.

FIG. 25 is a plot of efficiency as a function of normalized frequency comparing the transmission efficiencies of the system with conventional printed circuit board (PCB) resonators, as well as the systems with Design-1 and Design-2 printed circuit board (PCB) resonators according to various embodiments.

FIG. 26 shows a schematic of a wireless power transfer (WPT) system according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g. within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the resonators are analogously valid for the other resonators/systems. Similarly, embodiments described in the context of a method are analogously valid for a resonator/system, and vice versa.

Various embodiments may address one or more issues facing existing resonators. Various embodiments may exhibit longer operating frequency range, higher quality (Q) factor and/or improved energy efficiency.

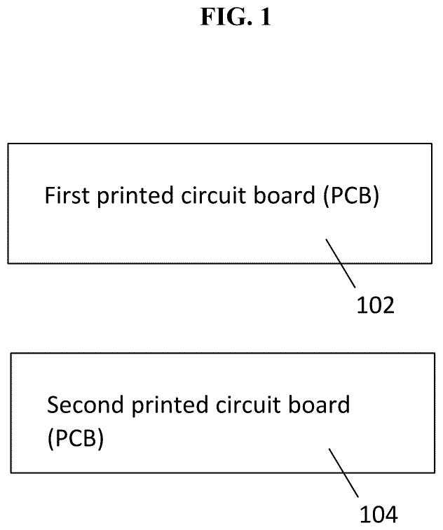

FIG. 1 shows a general illustration of a printed circuit board (PCB) resonator according to various embodiments. The printed circuit board (PCB) resonator may include a first printed circuit board (PCB) 102 including a first printed circuit board (PCB) substrate having only one side printed with a first coil. The printed circuit board (PCB) resonator may also include a second printed circuit board (PCB) 104 spaced apart from the first printed circuit board (PCB) 102, the second printed circuit board (PCB) 104 including a second printed circuit board (PCB) substrate having only one side printed with a second coil. The first printed circuit board (PCB) substrate may include slots between portions of the first printed circuit board (PCB) substrate in contact with the first coil. The second printed circuit board (PCB) substrate may include slots between portions of the second printed circuit board (PCB) substrate in contact with the second coil.

In other words, the printed circuit board (PCB) resonator may include two printed circuit boards (PCBs) with a gap between them. Each of the two PCBs 102, 104 may include a PCB substrate and a coil on a surface of the substrate. The surface of the substrate that is not covered by the coil may include a slot (alternatively referred to as trench).

For avoidance of doubt, FIG. 1 is intended to illustrate features of the PCB resonator according to various embodiments, and is not intended to limit the size, shapes, orientation, arrangement, relative dimensions etc. of the various features.

In various embodiments, the second printed circuit board (PCB) 104 may be spaced apart from the first printed circuit board (PCB) 102 by an air gap. The first printed circuit board (PCB) 102 and the second printed circuit board (PCB) 104 may be separated by a gap including air. Air has a dielectric loss tangent of 0.00005, while that of a low-cost PCB FR4 material is 0.022, and that of a low-loss PCB material such as Roger RO 4350 material is 0.0037. In various other embodiments, the first printed circuit board (PCB) 102 and the second printed circuit board (PCB) 104 may be separated by a gap including any suitable material with a very low dielectric loss tangent, e.g. an inert gas such as nitrogen gas or vacuum; or a thin insulation material with a low dielectric loss tangent, such as mica. In various embodiments, the second printed circuit board (PCB) 104 may be spaced apart from the first printed circuit board (PCB) 102 by a sheet of non-conductive material with a dielectric constant and a loss tangent lower than that of a printed circuit board (PCB) material included in the first printed circuit board (PCB) substrate and the second printed circuit board (PCB) substrate. While an air gap may provide the lowest inter-capacitance and dielectric power loss, other materials such as mica may also be used. In various embodiments, the first printed circuit board (PCB) 102 and the second printed circuit board (PCB) 104 may be separated by a gap including any suitable material having a dielectric loss tangent less than a dielectric loss tangent of a typical PCB material, such as PCB FR4 material or Roger RO 4350 material.

In various embodiments, the slots of the first printed circuit board (PCB) substrate and/or the slots of the second printed circuit board (PCB) substrate may include air. In various other embodiments, the slots of the first printed circuit board (PCB) substrate and/or the slots of the second printed circuit board (PCB) substrate may include an inert gas such as nitrogen gas or vacuum.

In various embodiments, the first coil printed on the first printed circuit board (PCB) substrate and the second coil printed on the second printed circuit board (PCB) substrate may face each other.

As mentioned above, the first printed circuit board (PCB) 102 may include the first printed circuit board (PCB) substrate and the first coil on one side of the first printed circuit board (PCB) substrate, while the second printed circuit board (PCB) 104 may include the second printed circuit board (PCB) substrate and the second coil on one side of the second printed circuit board (PCB) substrate. The opposing further side of the first printed circuit board (PCB) substrate (i.e. the further side which is opposite the side of the first printed circuit board (PCB) substrate printed with the first coil) may be devoid of a coil. Likewise, the opposing further side of the second printed circuit board (PCB) substrate (i.e. the further side which is opposite the side of the second printed circuit board (PCB) substrate printed with the second coil) may be devoid of a coil.

In various embodiments, the printed circuit board (PCB) resonator may be devoid of a magnetic core.

In various embodiments, the first coil may surround a hollow space (of the first printed circuit board (PCB) substrate). The hollow space may be in a center of the first printed circuit board (PCB) substrate and may extend from the side of the first printed circuit board (PCB) substrate to the opposing further side of the first printed circuit board (PCB) substrate. Likewise, the second coil may surround a hollow space (of the second printed circuit board (PCB) substrate). The hollow space may be in a center of the second printed circuit board (PCB) substrate and may extend from the side of the second printed circuit board (PCB) substrate to the opposing further side of the second printed circuit board (PCB) substrate.

In various embodiments, the first coil may include a first plurality of concentric turns. The first plurality of concentric turns may be in electrical connection with one another. Adjacent or neighboring turns of the first plurality of concentric turns may be electrically and physically connected. A turn of the first plurality of concentric turns may include a portion that connects to an adjacent or neighboring turn of the first plurality of concentric turns. The first coil may be a continuous, electrically conductive trace. In various embodiments, the first coil may have a shape of e.g. a regular spiral or a square spiral. The first plurality of concentric turns may refer to different nested segments of the electrically conductive trace.

Likewise, in various embodiments, the second coil may include a second plurality of concentric turns. The second plurality of concentric turns may be in electrical connection with one another. Adjacent or neighboring turns of the second plurality of concentric turns may be electrically and physically connected. A turn of the second plurality of concentric turns may include a portion that connects to an adjacent or neighboring turn of the second plurality of concentric turns. The second coil may be a continuous, electrically conductive trace. In various embodiments, the second coil may have a shape of e.g. a regular spiral or a square spiral. The second plurality of concentric turns may refer to different nested segments of the electrically conductive trace.

In various embodiments, trace widths of the first plurality of concentric turns may be proportionally decreased from an outermost turn of the first plurality of concentric turns to an innermost turn of the first plurality of concentric turns. Trace widths of the second plurality of concentric turns may be proportionally decreased from an outermost turn of the second plurality of concentric turns to an innermost turn of the second plurality of concentric turns.

In various embodiments, the first plurality of concentric turns may be spaced equally. There may be a predetermined spacing between adjacent or neighboring turns of the first plurality of concentric turns. In various embodiments, the second plurality of concentric turns may be spaced equally. There may be a predetermined spacing between adjacent or neighboring turns of the second plurality of concentric turns.

In various embodiments, the first coil may include a single input-output terminal. The second coil may include a single input-output terminal.

In various embodiments, the printed circuit board (PCB) resonator may also include a via electrically connecting the input-output terminal of the first coil and the input-output terminal of the second coil to form a parallel resonator.

In various other embodiments, the printed circuit board (PCB) resonator may be devoid of a via electrically connecting the input-output terminal of the first coil and the input-output terminal of the second coil, thereby forming a series resonator.

In various embodiments, the printed circuit board (PCB) resonator may be configured to generate a magnetic field between the first coil and the second coil during operation.

In various embodiments, the printed circuit board (PCB) resonator may be configured to generate electric fields within each of the first coil (e.g. between different turns of the first plurality of turns) and the second coil (e.g. between different turns of the second plurality of turns), and between the first coil and the second coil during operation.

In various embodiments, the printed circuit board (PCB) resonator may be configured to operate at a predetermined resonant frequency, or within a range of +5% or −5% of the predetermined resonant frequency.

In various embodiments, the printed circuit board (PCB) resonator may be a transmitter resonator or a receiver resonator.

Various embodiments may provide a wireless power transfer (WPT) system including one or more printed circuit board (PCB) resonators as described herein.

In various embodiments, the one or more printed circuit board (PCB) resonators may include a transmitter resonator and a receiver resonator. During operation, the transmitter resonator may transfer power from the transmitter resonator to the receiver resonator via electromagnetic fields. The electromagnetic fields may be electric fields (capacitive coupling), magnetic fields (inductive coupling) or a combination of both electric fields and magnetic fields.

In various embodiments, the wireless power transfer system may further include a first metasurface shield and a second metasurface shield such that the transmitter resonator and the receiver resonator are between the first metasurface shield and the second metasurface shield. The first metasurface shield may include a plurality of metasurface structures. Likewise, the second metasurface shield may include a plurality of metasurface structures.

In various embodiments, the wireless power transfer system may also include a receiver circuit arrangement in electrical connection with the receiver resonator. The wireless power transfer system may further include a power inverter in electrical connection with the transmitter resonator. The wireless power transfer system may additionally include a gate drive in electrical connection with the power inverter. The wireless power transfer system may also include a system controller in electrical connection with the gate drive.

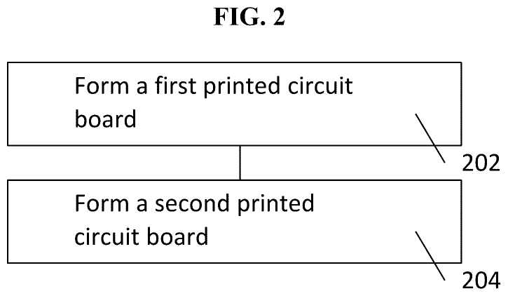

FIG. 2 shows a general illustration of a method of forming a printed circuit board (PCB) resonator according to various embodiments. The method may, in 202, include forming a first printed circuit board (PCB) including a first printed circuit board (PCB) substrate having only one side printed with a first coil. The method may also include, in 204, forming a second printed circuit board (PCB) spaced apart from the first printed circuit board (PCB), the second printed circuit board (PCB) including a second printed circuit board (PCB) substrate having only one side printed with a second coil. The first printed circuit board (PCB) substrate may include slots between portions of the first printed circuit board (PCB) substrate in contact with the first coil. The second printed circuit board (PCB) substrate may include slots between portions of the second printed circuit board (PCB) substrate in contact with the second coil.

In other words, the method may include forming two PCBs, each including a PCB substrate and a coil on a surface of the PCB substrate. The portions of the PCB substrates not covered by the coil may have or include slots.

For avoidance of doubt, FIG. 2 is not intended to limit the sequence of the various steps. For instance, step 204 can occur before, at the same time or after step 202.

In various embodiments, the second printed circuit board (PCB) may be spaced apart from the first printed circuit board (PCB) by an air gap. In various other embodiments, the second printed circuit board (PCB) may be spaced apart from the first printed circuit board (PCB) by a sheet of non-conductive material with a dielectric constant and a loss tangent lower than that of a printed circuit board (PCB) material included in the first printed circuit board (PCB) substrate and the second printed circuit board (PCB) substrate.

In various embodiments, the first coil printed on the first printed circuit board (PCB) substrate and the second coil printed on the second printed circuit board (PCB) substrate may face each other.

In various embodiments, the printed circuit board (PCB) resonator may be devoid of a magnetic core.

In various embodiments, the first coil may surround a hollow space. The second coil may surround a hollow space.

In various embodiments, trace widths of the first plurality of concentric turns may be proportionally decreased from an outermost turn of the first plurality of concentric turns to an innermost turn of the first plurality of concentric turns. Trace widths of the second plurality of concentric turns may be proportionally decreased from an outermost turn of the second plurality of concentric turns to an innermost turn of the second plurality of concentric turns.

In various embodiments, the first plurality of concentric turns may be spaced equally. The second plurality of concentric turns may be spaced equally.

In various embodiments, the first coil may include a single input-output terminal. The second coil may include a single input-output terminal.

In various embodiments, the method may include forming a via electrically connecting the input-output terminal of the first coil and the input-output terminal of the second coil to form a parallel resonator.

In various embodiments, the printed circuit board (PCB) resonator may be devoid of a via electrically connecting the input-output terminal of the first coil and the input-output terminal of the second coil, thereby forming a series resonator.

In various embodiments, the printed circuit board (PCB) resonator may be configured to generate a magnetic field between the first coil and the second coil during operation.

In various embodiments, the printed circuit board (PCB) resonator may be configured to generate electric fields within each of the first coil and the second coil and between the first coil and the second coil during operation.

In various embodiments, the printed circuit board (PCB) resonator may be configured to operate at a predetermined resonant frequency, or within a range of +5% or −5% of the predetermined resonant frequency.

Various embodiments may relate to a method of forming a wireless power transfer (WPT) system. The method may also include forming one or more printed circuit board (PCB) resonators as described herein.

In various embodiments, the one or more printed circuit board (PCB) resonators may include a transmitter resonator and a receiver resonator. The wireless power transfer system may further include a first metasurface shield and a second metasurface shield such that the transmitter resonator and the receiver resonator are between the first metasurface shield and the second metasurface shield.

In various embodiments, the method may include electrically connecting a receiver circuit arrangement with the receiver resonator. The method may also include electrically connecting a power inverter with the transmitter resonator. The method may additionally include electrically connecting a gate drive with the power inverter. The method may further include electrically connecting a system controller with the gate drive.

Various embodiments may relate to PCB resonator designs that have been investigated, and shown to have significant advancement over existing designs based on the same PCB dimensions. Various embodiments may relate to PCB winding designs that take advantage of the low relative permittivity of air. Various embodiments may be based on two layers of PCB winding structures with an airgap between them to create distributed inductive-capacitive resonators. Compared with conventional designs, various embodiments may have the flexibility of being configurated as either series or parallel resonators, have much high resonant frequency, have much higher quality (Q) factor, and/or have much higher transmission efficiency.

The structural differences between two proposed PCB resonator designs according to various embodiments and the conventional PCB resonator design are provided herein.

In the three cases, the winding patterns are printed on the PCBs of the same dimensions. Accurate models of the proposed PCB resonator designs are included and explained. In addition, the theoretical and practical characteristics of the three designs are also presented. Based on the same test platform of a domino WPT system, the three PCB resonator designs are tested for their transmission efficiency. A comparison of the Q factor, bandwidth, and transmission efficiency is included to confirm the advantages of the proposed PCB resonator structures.

The conventional PCB resonator design uses PCB windings printed on the two sides of a circular PCB disc as relay resonators in domino wireless power transfer (WPT) systems. It has been demonstrated that printed spiral winding with variable width has low resistance. To provide a common platform for comparison, the spiral and planar PCB windings with variable widths are printed as resonators in this study. Each PCB has a dimeter of 21 cm and the outermost circular winding a dimeter of 20 cm. The printed windings for the conventional design and the two proposed PCB resonator designs according to various embodiments are first optimized using the COMSOL electromagnetic design software to maximize the Q factor:

$$Q = \frac{{f}_{0}}{Δ f} \qquad ( 1 )$$

where fₒ is the resonant frequency and Δf is the 3 decibels (dB) bandwidth.

In this comparative study, the three PCB resonator structures may be summarized as follows: (1) the conventional PCB resonator design is adopted from optimized design as reported previously, with the two PCB windings printed on the two sides of the same PCB board. The dielectric material between the two planar PCB windings is the standard FR-4 (flame retardant-4) PCB material. (2) Design-1 is based on the same conventional PCB windings, but with the two planar PCB windings printed on two different PCB boards arranged in a co-axial manner and separated with a uniform airgap to reduce the inter-winding capacitance. (3) Design-2 retains the two-layer structure of Design-1, but the two PCB windings are optimized specifically for the two-layer structure with an airgap between the two planar PCB windings and with air-trenches between adjacent turns to further reduce the intra-winding capacitance.

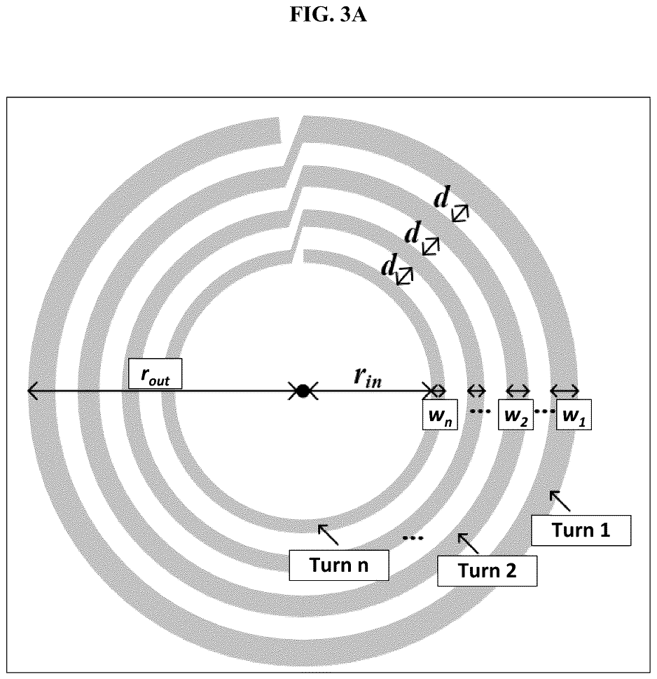

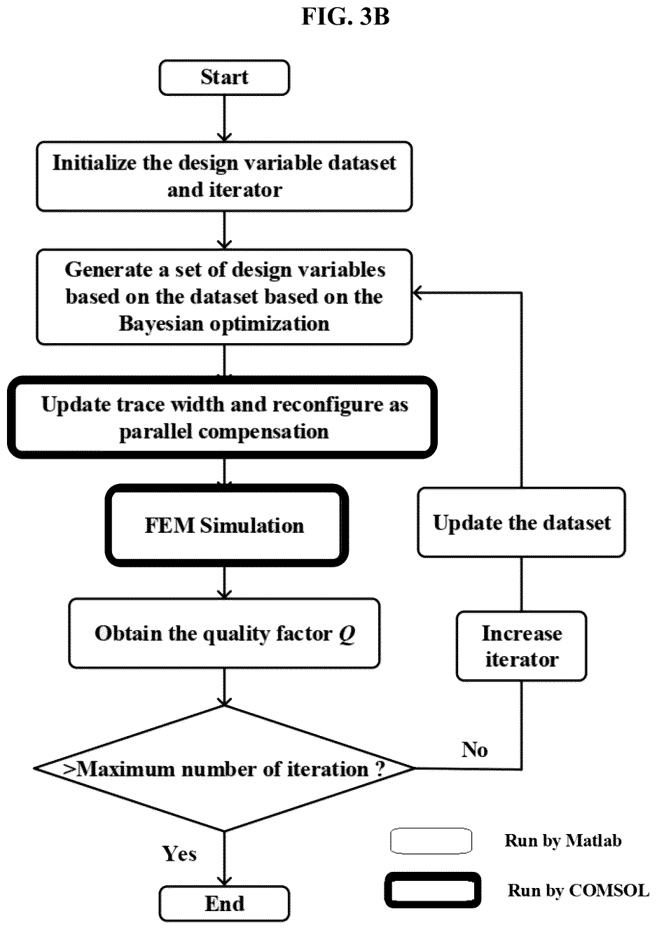

The COMSOL software is used to optimize the two winding structures specifically to its two-layer structure. To fit the Bayesian optimization framework, the PCB resonator is reconfigured as parallel compensation. FIG. 3A is a schematic showing the design variables for copper traces of a printed circuit broad (PCB) winding or coil according to various embodiments. The winding or coil may have n turns. The radius of the outermost trace may be indicated by rₒᵤₜ, the radius of the innermost copper trace may be indicated by rᵢₙ, and the distance between two adjacent traces or turns may be indicated by d. The trace widths may be indicated by w₁, w₂, . . . . wₙ. It may be worth noting that proportional trace width is adopted, i.e., w₂/w₁=w₃/w₂ . . . =wₙ/wₙ₋₁=k. With the ratio k, trace width of the first trace w₁, and the number of turns n, the trace width of the n-turn PCB coil can be automatically generated. The use of proportional trace width can effectively reduce the number of unknown variables and expedite the optimization process. FIG. 3B is a flowchart of the optimization process according to various embodiments. In this example of the optimization process, rₒᵤₜ is set at 100 mm, and the constraints of the other optimization variables are set as rᵢₙ∈[26 mm, 70 mm], w₁∈[0.5 mm, 15 mm], k∈[0.8, 1.2], d∈[0.5 mm, 4 mm], n∈[1 turn, 100 turns].

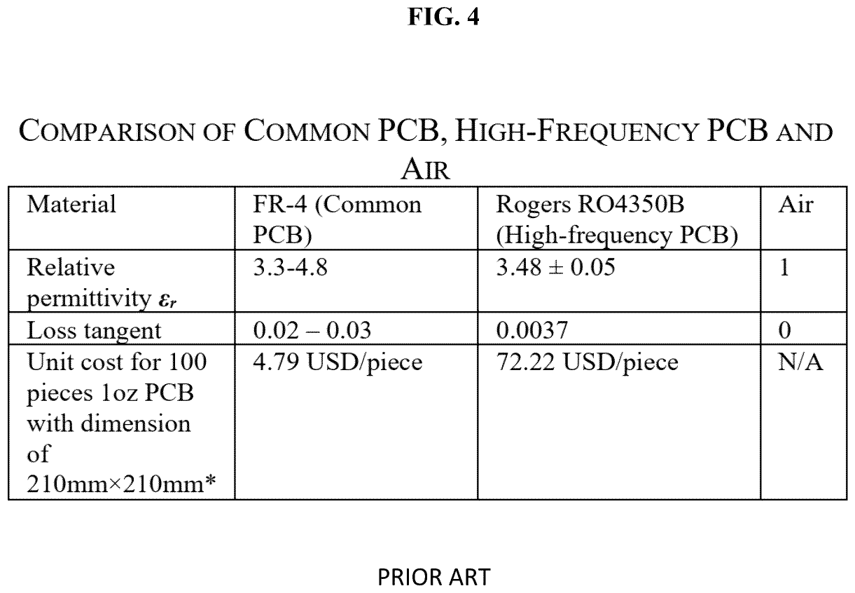

After starting the optimization process, the design variables dataset and iterator may be initialized. A set of feasible design variables may then be generated based on the dataset. Next, the design variables may be converted into specific trace width of the PCB resonator. The trace width may be sent to COMSOL simulation software to update the three-dimensional (3D) structure. In addition, the PCB resonator may be reconfigured as parallel compensation by short-circuiting the input-output terminals. The quality factor of the PCB resonator can be directly obtained by running the eigenfrequency study. Finally, the resulting quality factor and trace width may be used to update the dataset. The optimization process may end if the iterator exceeds the maximum number of iterations. Another factor affecting the Q factor may be the loss tangent of the PCB materials. FIG. 4 is a table comparing the relative permittivity (Er), loss tangent, and unit costs of a common printed circuit board (PCB), a high frequency printed circuit board (PCB), and air. Note that the relative permittivity of PCB materials is typically over three times that of air. As the price of the high frequency PCB material is much higher than the common PCB material, the FR-4 PCB material is used as a comparison platform.

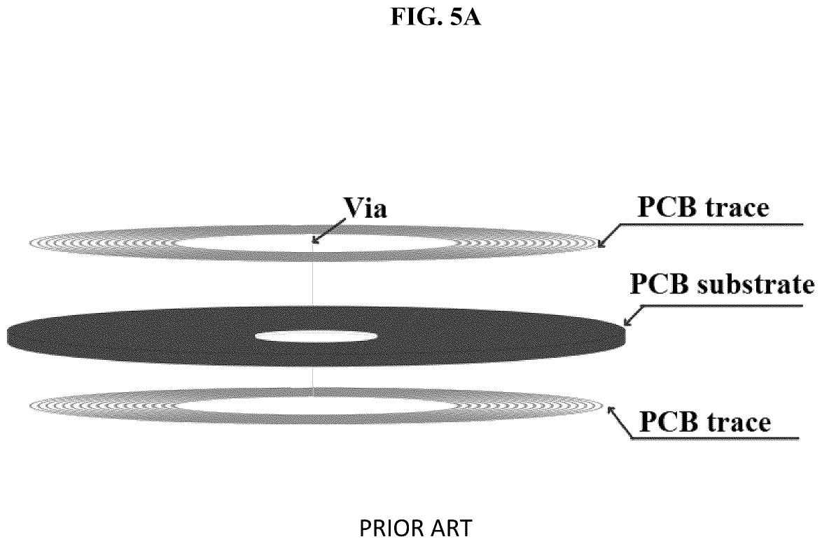

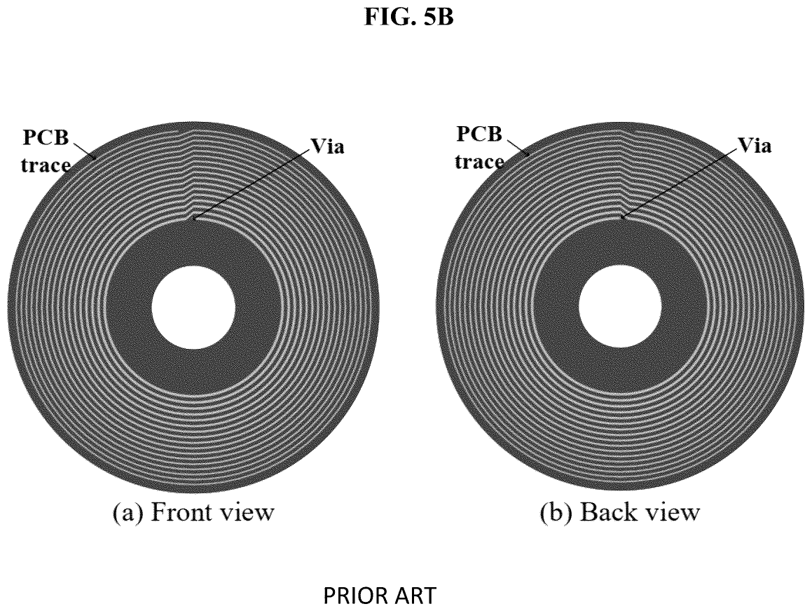

FIG. 5A is a schematic showing an exploded view of a conventional printed circuit board (PCB) resonator. The conventional printed circuit board (PCB) resonator includes two printed spiral windings or coils on two sides of the same printed circuit board (PCB). The two spiral windings are connected through a via. Based on the optimization procedure described in FIG. 3B, the winding patterns or coils are shown in FIG. 5B. FIG. 5B is a schematic showing a front view and a back view of the conventional printed circuit board (PCB) resonator shown in FIG. 5A. The two spiral windings or coils form the distributed inductor, which accounts for the magnetic field created in the winding structure whenever there is a current in the winding. The main distributed capacitance is provided by the electric field between the copper traces or tracks between the two sides of the PCB. The electric field appears across the PCB material with a relative permittivity of typically 3.3 to 4.8 (FIG. 4). There is also (stray) intra-capacitance between adjacent copper tracks on the same side of the PCB. Note that the conventional PCB resonator in FIG. 5A is inherently a parallel resonant tank. It can only be re-configurated into a series resonant tank when the via connection between the two spiral coils printed on both sides of the PCB is removed.

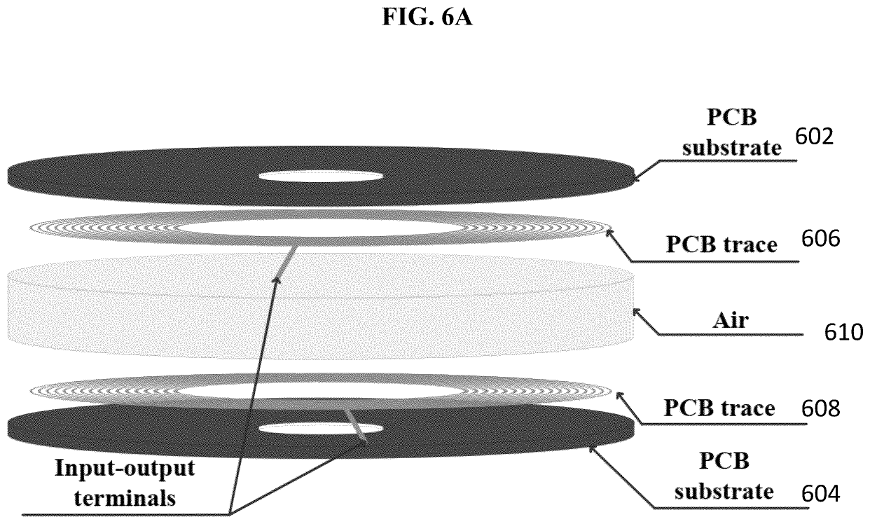

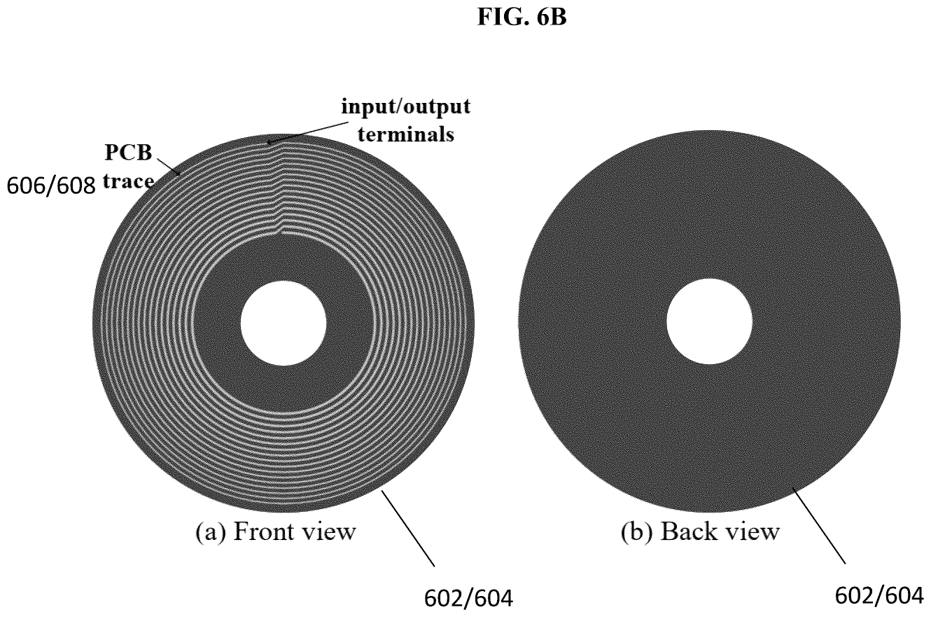

The capacitance between the printed spiral coils on the two sides of the PCB is affected by the permittivity of the PCB materials in the conventional PCB resonator structure in FIG. 5A. FIG. 4 indicates that the permittivity of the PCB materials is higher than that of air. Therefore, the inter-capacitance between the two printed spiral coils can be reduced if the two printed coils are printed on two separate PCBs and are separated by an air gap as shown in FIG. 6A.

FIG. 6A is a schematic showing an exploded view of a printed circuit board (PCB) resonator (Design-1) according to various embodiments. For Design-1, two PCBs 602, 604 may be used to form the resonator with one spiral coil or winding 606, 608 printed on each PCB 602, 604. The coils or windings 606, 608 may face each other. FIG. 6B is a schematic showing a front view and a back view of the printed circuit board (PCB) resonator shown in FIG. 6A according to various embodiments. The two PCBs 602, 604 may be separated by an air gap 610. With the material between the two printed coils 606, 608 changed from PCB materials to air, the inter-capacitance of the resonator can be reduced, therefore increasing the resonant frequency of the resonator. Since the energy efficiency of the resonator increases with the Q factor and operating frequency, Design-1 is expected to offer a higher energy efficiency as shown later.

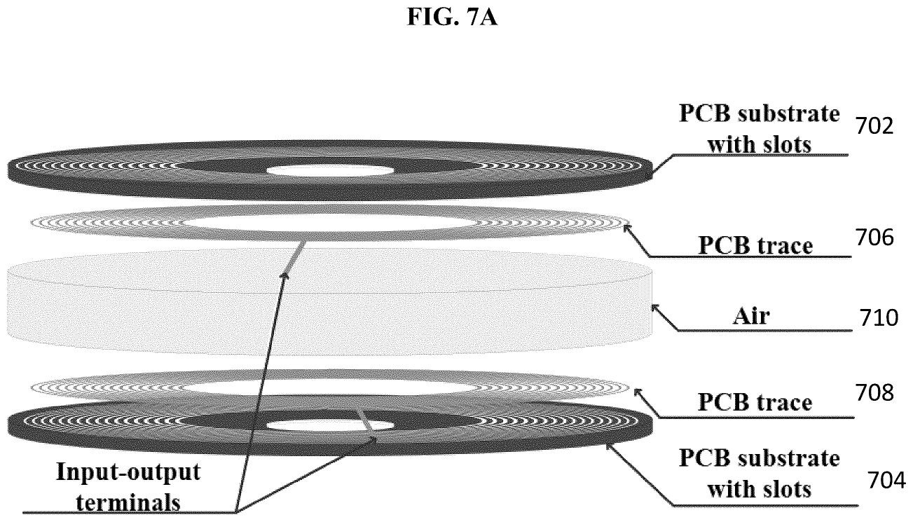

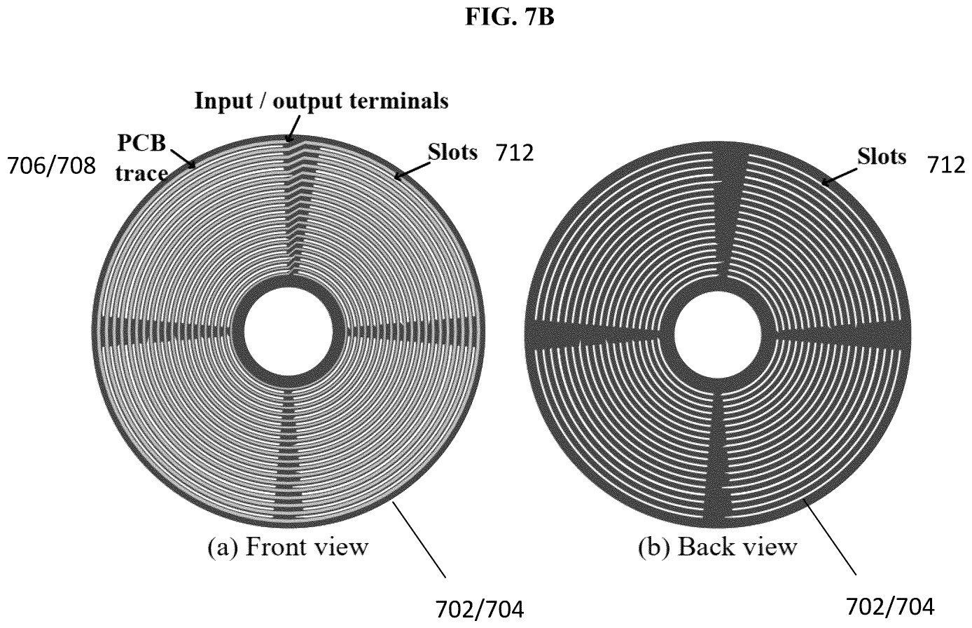

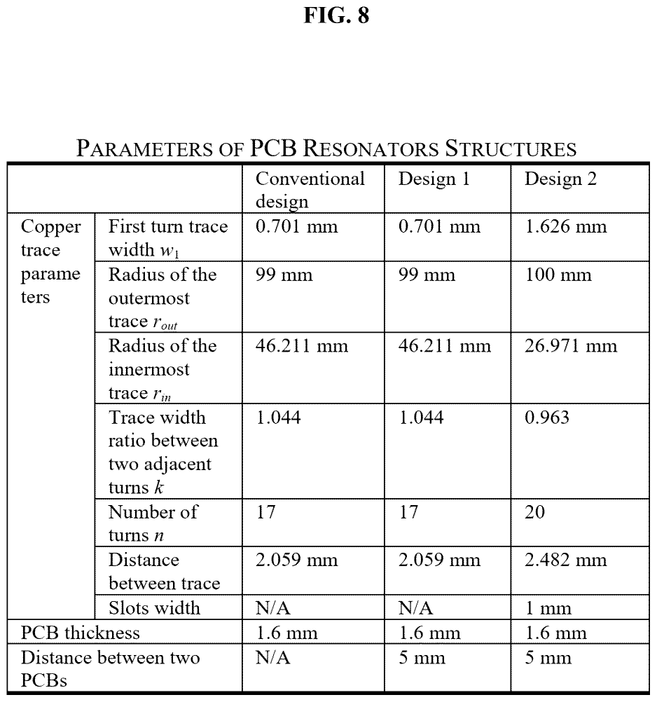

FIG. 7A is a schematic showing an exploded view of a printed circuit board (PCB) resonator (Design-2) according to various embodiments. Design-2 may be optimized with the COMSOL software for maximum Q factor, and may therefore have a different number of turns. Two PCBs 702, 704 may be used to form the resonator with one spiral coil or winding 706, 708 printed on each PCB 702, 704. The coils or windings 706, 708 may face each other. FIG. 7B is a schematic showing a front view and a back view of the printed circuit board (PCB) resonator shown in FIG. 7A according to various embodiments. The two PCBs 702, 704 may be separated by an air gap 710 to reduce inter-capacitance. The structure of Design-2 may further be improved by reducing the intra-capacitance between adjacent turns of the printed spiral coils 706, 708 by removing some part of PCB material between the adjacent turns to form air trenches or slots 712. Design-2 may have less intra-capacitance because of the formation of trenches or slots 712 (with the PCB materials removed) as shown in FIG. 7B. Note that not all PCB material is removed, because it may be necessary to use some PCB material to provide support for the printed coil. FIG. 8 is a table summarizing the conventional printed circuit board (PCB) resonator as well as Design-1 and Design-2 printed circuit board (PCB) resonators according to various embodiments. As shown in FIG. 8, the number of turns of the Design-2 printed circuit board (PCB) resonator may be different from the Design-1 printed circuit board (PCB) resonator. The Design-2 printed circuit board (PCB) resonator may have advantages over the Design-1 printed circuit board (PCB) resonator as well as the conventional printed circuit board (PCB) resonator as shown later.

The Design-1 printed circuit board (PCB) resonator and the Design-2 printed circuit board (PCB) resonator are tested and compared with the conventional printed circuit board (PCB) resonator in two ways. Firstly, their impedance-frequency characteristics, resonant frequencies and Q factors are modeled, measured and compared. Secondly, the three PCB resonator structures are used to form three domino wireless power transfer (WPT) systems with the same transmission distance so that their transmission efficiencies can be measured and compared.

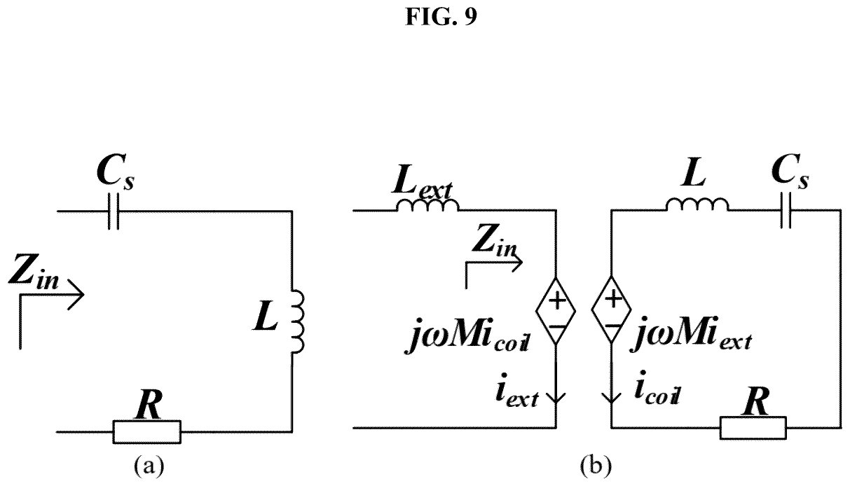

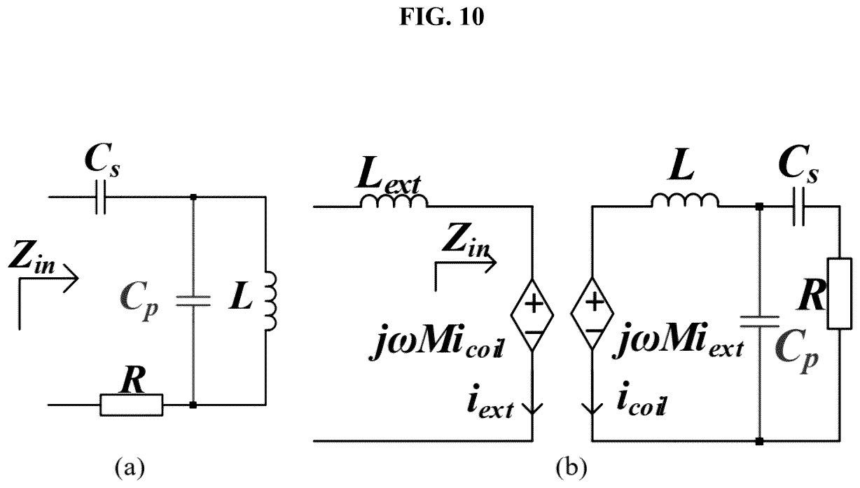

The traditional lumped-element equivalent circuit for inductive-capacitive (LC) resonators is to use a second-order circuit as shown in FIG. 9. FIG. 9 shows (a) a second-order circuit according to various embodiments; and (b) equivalent circuit for a wireless power transfer (WPT) system with secondary parallel resonant circuit according to various embodiments. However, for printed resonators, both the inductance and capacitance may be distributed. More importantly, it may be necessary to consider both the inter-capacitance (Cₛ) and the intra-capacitance (Cₚ) of the winding structures because the resonant frequency would be in the mega-Hertz (MHz) range. For this reason, an extra capacitor may be added in a third-order resonant circuit to represent the intra-capacitance as shown in FIG. 10. FIG. 10 shows (a) a third-order circuit according to various embodiments; and (b) equivalent circuit for a wireless power transfer (WPT) system with secondary parallel resonant circuit for representing printed circuit board (PCB) resonators according to various embodiments.

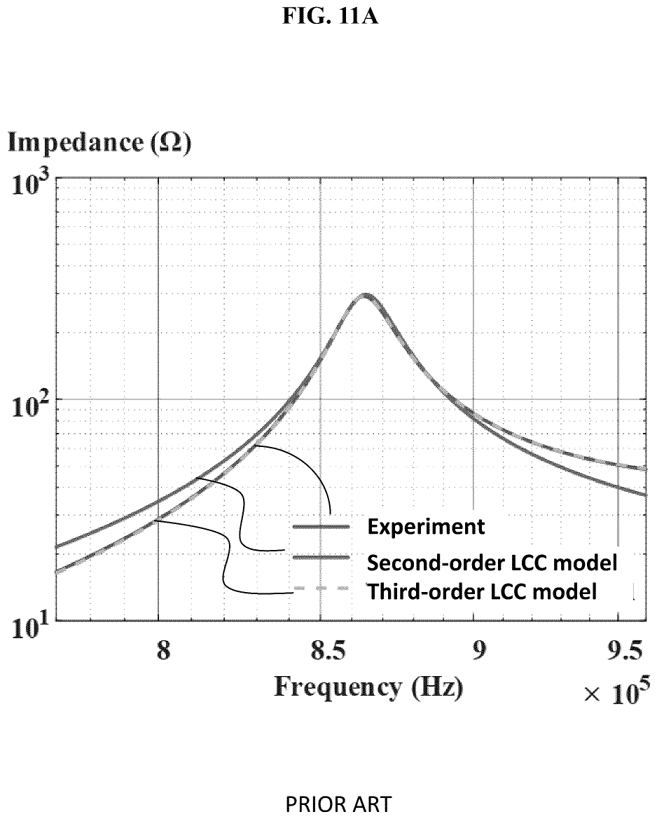

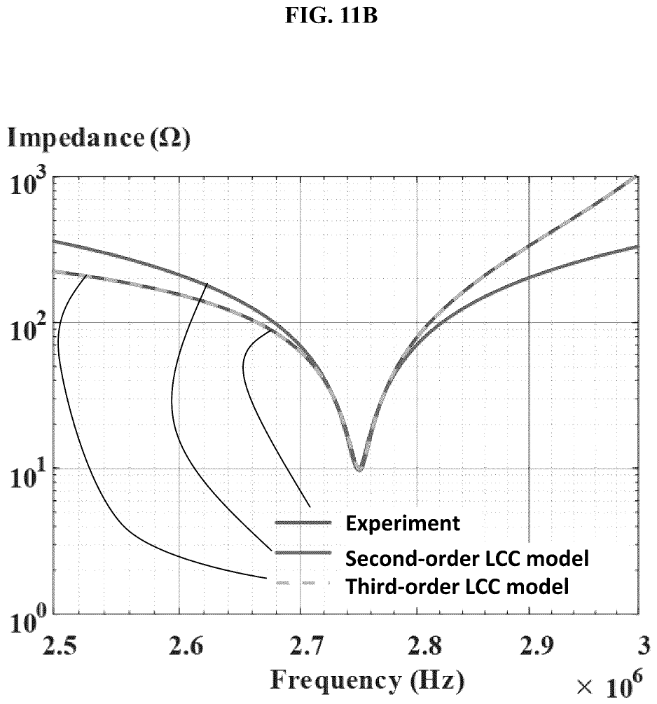

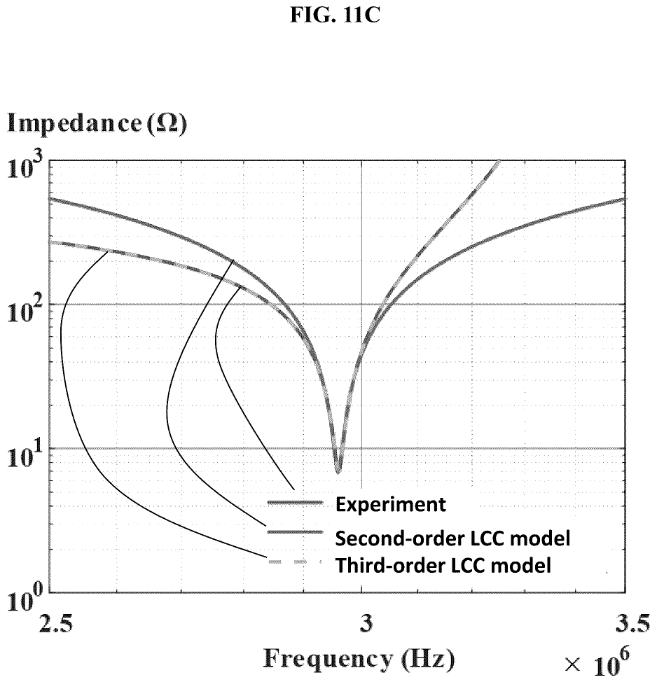

For the sake of fair comparison, the three PCB resonators (i.e the conventional PCB resonator, Design-1 and Design-2) are initially configurated as parallel resonators for parameter measurements with an impedance analyzer. A series-resonant transmitter is used to excite the three PCB resonator structures shown in FIG. 10(b). The impedance-frequency plots of the three different PCB resonators are practically measured and compared with the simulated results based on the second-order and third-order circuit models (FIGS. 11A-C).

FIG. 11A is a plot of impedance (in ohms or Ω) as a function of frequency (in Hertz or Hz) illustrating the measured and theoretical impedance curves of the conventional printed circuit board (PCB) resonator. FIG. 11B is a plot of impedance (in ohms or Ω) as a function of frequency (in Hertz or Hz) illustrating the measured and theoretical impedance curves of the Design-1 printed circuit board (PCB) resonator according to various embodiments. FIG. 11C is a plot of impedance (in ohms or Ω) as a function of frequency (in Hertz or Hz) illustrating the measured and theoretical impedance curves of the Design-2 printed circuit board (PCB) resonator according to various embodiments.

Since the conventional PCB resonator is of a “parallel” resonator, its impedance measurement procedure is illustrated as follows: A coil with known impedance is used a transmitter coil. Its self-impedance (Z_{T}) is first measured. A conventional PCB resonator is placed near the transmitter coil. By exciting the transmitter coil and measuring the input impedance (Zᵢₙ) of the magnetic coupled system, the impedance of the conventional PCB resonator (Z_{CR}) is obtained from Zᵢₙ=Z_{T}−Z_{CR}.

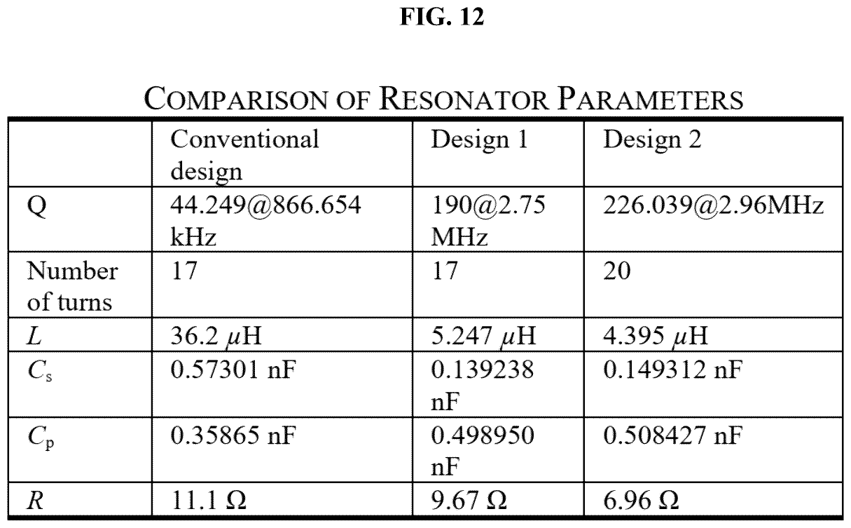

For Design-1 and Design-2, they can be configurated as “series” resonators and therefore their impedance can be measured with an impedance analyzer directly without using a transmitter. These simulated and measured impedance-frequency plots are shown in FIGS. 11A-C for the conventional PCB resonator (as a parallel resonator), Design-1 (as a series-resonator) and Design-2 (as a series resonator), respectively. In all three cases, the simulated results of the third-order circuit models fit very well with the measured ones. The simulated results of the second-order model deviate increasingly from practical measurements as the frequency moves away on both sides from the respective resonant frequencies. Therefore, the third-order equivalent circuit should be used for analysis of PCB resonators. The characteristics of the three resonators are tabulated in FIG. 12. FIG. 12 is a table comparing parameters of the conventional printed circuit board (PCB) resonator, as well as Design-1 printed circuit board (PCB) and Design-2 printed circuit board (PCB) resonators according to various embodiments.

From FIG. 12, the Q factor of the conventional resonator is 44.25 at the resonant frequency of 866.7 kHz. The Q factors of the Design-1 and Design-2 PCB resonators are 190 at a resonant frequency of 2.75 MHz and 226 at 2.96 MHz, respectively. The improvements in the Q factor are therefore 4.29 times in Design-1 and 5.11 times in Design-2. The resonant frequencies change from 866 kHz in the conventional PCB resonator to 2.75 MHz in Design-1 and 2.96 MHz in Design-2. The increase in the resonant frequencies may be mainly due to the reduction in the self-inductance and the inter-capacitance. The equivalent winding resistances of Design-1 and Design-2 may be smaller than that of the conventional PCB resonator. The comparative results in FIG. 12 may confirm that various embodiments, namely Design-1 and Design-2, have superior characteristics than the conventional PCB resonator.

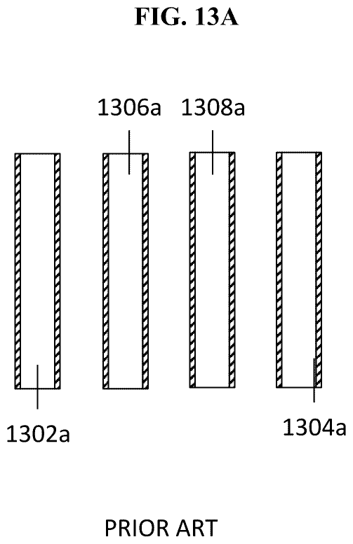

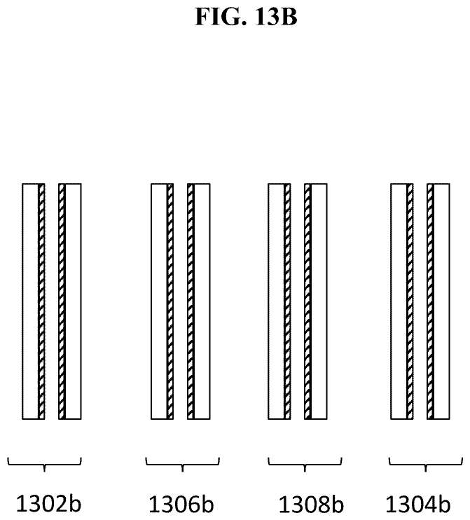

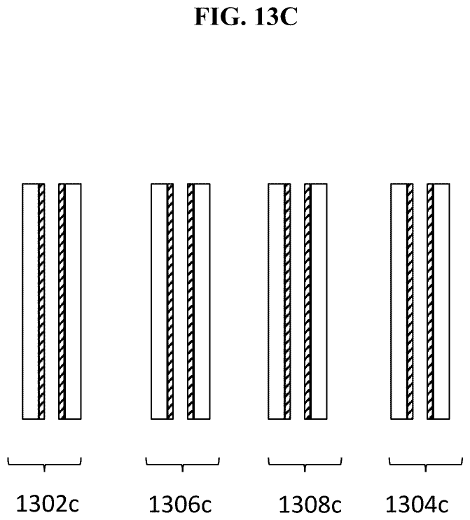

The three different PCB resonator structures may be configurated to form 4-resonators WPT systems as shown in FIGS. 13A-C. FIG. 13A shows an image of a wireless power transfer system including four conventional printed circuit board (PCB) resonators. The system may include a transmitter resonator 1302a, a receiver resonator 1304a and two relay resonators 1306a, 1308a between the transmitter resonator 1302a and the receiver resonator 1304a. FIG. 13B shows an image of a wireless power transfer system including four Design-1 printed circuit board (PCB) resonators according to various embodiments. The system may include a transmitter resonator 1302b, a receiver resonator 1304b and two relay resonators 1306b, 1308b between the transmitter resonator 1302b and the receiver resonator 1304b. FIG. 13C shows an image of a wireless power transfer system including four Design-2 printed circuit board (PCB) resonators according to various embodiments. The system may include a transmitter resonator 1302c, a receiver resonator 1304c and two relay resonators 1306c, 1308c between the transmitter resonator 1302c and the receiver resonator 1304c.

The first and the fourth PCB resonators are configurated as series resonators. The second and the third resonators are configurated as parallel resonators, and may be used as relay resonators. The distance between adjacent PCB resonators is kept the same in each domino WPT system. Two distances are used for practical evaluation. The matrix system equation for the 4-resonators domino WPT system is provided by Equation (2) below.

The state-space matrix equations for the 4-resonators domino WPT are derived as:

$$[ \begin{matrix}\frac{{di}_{L\_matrix}}{dt} \\ \frac{{dv}_{p\_matrix}}{dt} \\ \frac{{dv}_{s\_matrix}}{dt}\end{matrix} ] = [ \begin{matrix}0 & {L}_{matrix}^{- 1} & 0 \\ - {C}_{p\_matrix}^{- 1} & - {C}_{p\_matrix}^{- 1} {R}_{matrix}^{- 1} & - {C}_{p\_matrix}^{- 1} {R}_{matrix}^{- 1} \\ 0 & - {C}_{s\_matrix}^{- 1} {R}_{matrix}^{- 1} & - {C}_{s\_matrix}^{- 1} {R}_{matrix}^{- 1}\end{matrix} ] [ \begin{matrix}{i}_{L\_matrix} \\ {v}_{p\_matrix} \\ {v}_{s\_matrix}\end{matrix} ] + [ \begin{matrix}0 \\ {C}_{p\_matrix}^{- 1} {v}_{in\_matrix} \\ {C}_{s\_matrix}^{- 1} {v}_{in\_matrix}\end{matrix} ] {v}_{in} \qquad ( 2 )$$

$$[ \begin{matrix}{i}_{in} \\ {i}_{R 2} \\ {i}_{R 3} \\ {i}_{R 4}\end{matrix} ] = [ 0 - {R}_{matrix}^{- 1} - {R}_{matrix}^{- 1} ] [ \begin{matrix}{i}_{L\_matrix} \\ {v}_{p\_matrix} \\ {v}_{s\_matrix}\end{matrix} ] + [ {v}_{in\_matrix} ] {v}_{in} \qquad ( 3 )$$

$$\begin{matrix}where {L}_{matrix} = [ \begin{matrix}{L}_{1} & {M}_{12} & {M}_{13} & {M}_{14} \\ {M}_{21} & {L}_{2} & 0 & {M}_{24} \\ {M}_{31} & {M}_{32} & {L}_{3} & {M}_{34} \\ {M}_{41} & {M}_{42} & {M}_{43} & {L}_{4}\end{matrix} ] , {C}_{s\_matrix} = [ \begin{matrix}{C}_{s 1} & 0 & 0 & 0 \\ 0 & {C}_{s 2} & 0 & 0 \\ 0 & 0 & {C}_{s 3} & 0 \\ 0 & 0 & 0 & {C}_{s 4}\end{matrix} ] , {C}_{p\_matrix} = [ \begin{matrix}{C}_{p 1} & 0 & 0 & 0 \\ 0 & {C}_{p 2} & 0 & 0 \\ 0 & 0 & {C}_{p 3} & 0 \\ 0 & 0 & 0 & {C}_{p 4}\end{matrix} ] , {R}_{matrix} = [ \begin{matrix}{R}_{1} & 0 & 0 & 0 \\ 0 & {R}_{2} & 0 & 0 \\ 0 & 0 & {R}_{3} & 0 \\ 0 & 0 & 0 & {R}_{1} + {R}_{L}\end{matrix} ] , \\ {i}_{L\_matrix} = {[ {i}_{L 1} ( t ) , {i}_{L 2} ( t ) , {i}_{L 3} ( t ) , {i}_{L 4} ( t ) ]}^{T} {v}_{s\_matrix} = {[ {v}_{s 1} ( t ) , {v}_{s 2} ( t ) , {v}_{s 3} ( t ) , {v}_{s 4} ( t ) ]}^{T} , \\ {v}_{p\_matrix} = {[ {v}_{p 1} ( t ) , {v}_{p 2} ( t ) , {v}_{p 3} ( t ) , {v}_{p 4} ( t ) ]}^{T} , {v}_{in\_matrix} = {[ {R}_{1}^{- 1} , 0 , 0 , 0 ]}^{T} ,\end{matrix}$$

and 0 is the 4×4 zero matrix.

The efficiency of the domino system is written as

$$η = \frac{\frac{1}{T} {\int }_{0}^{T} {i}_{0}^{2} {R}_{L} dt}{\frac{1}{T} {\int }_{0}^{T} [ {i}_{0}^{2} ( {R}_{L} + {R}_{4} ) + {i}_{R 3}^{2} {R}_{3} + {i}_{R 2}^{2} {R}_{2} + {i}_{in}^{2} {R}_{1} ] dt} \qquad ( 4 )$$

In this test, the distance between adjacent PCB resonator is 10 cm and the load of 4-resonators domino WPT system R_{L}=250. To lower the complexity of the model, some parameters of the PCB resonators in the 4-resonators domino WPT system can be assumed to be identical, e.g., L₁=L₂=L₃=L₄, Cₛ₁=Cₛ₂=Cₛ₃=Cₛ₄, Cₚ₁=Cₚ₂=Cₚ₃=Cₚ₄, R₁=R₂=R₃=R₄. In addition, the mutual inductance between two PCB resonators with the same distance can be assumed to be identical, i.e., M₁₂=M₂₃=M₃₄, and M₁₃=M₂₄.

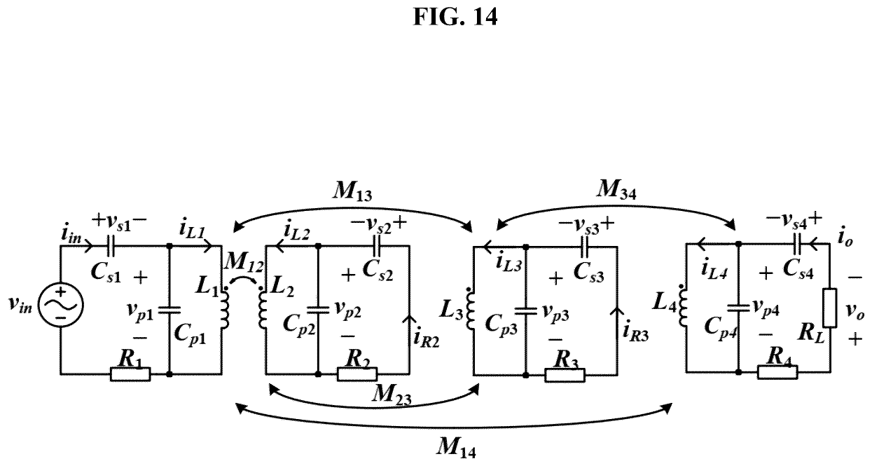

FIG. 14 shows an equivalent circuit model of the 4-resonators domino wireless power transfer (WPT) system according to various embodiments. By fitting the experimental input impedance data Z_{in_data} of the 4-resonators domino WPT system with 2-norm, the mutual inductance of the equivalent circuit model in FIG. 14 can be obtained as:

$${arg min}_{{M}_{12} , {M}_{13} , {M}_{14}} {‖ \vert \frac{{v}_{in} ( s )}{{i}_{in} ( s )} \vert - \vert {z}_{{in}_{data}} \vert ‖}_{2} \qquad ( 5 )$$

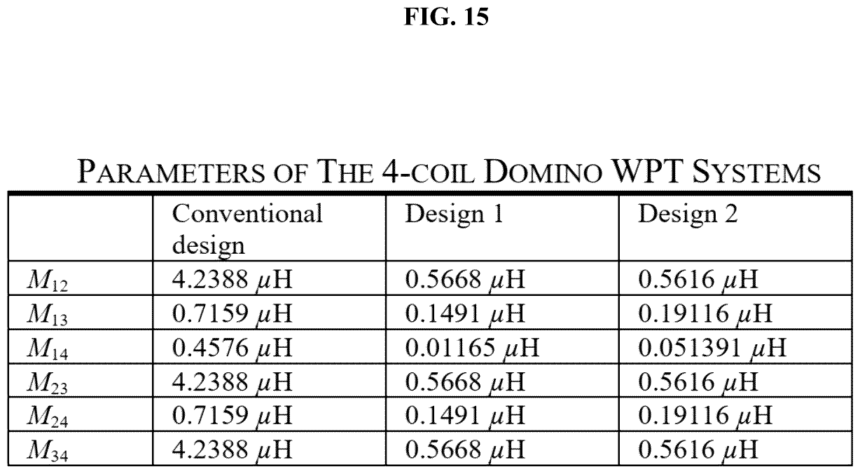

By using the corresponding parameters of the PCB resonators in FIG. 12, the resulted mutual inductance of the 4-resonators domino WPT system are shown in FIG. 15. FIG. 15 is a table showing the resulted mutual inductance of the 4-resonators domino wireless power transfer (WPT) systems of conventional printed circuit board (PCB) resonators as well as Design-1 and Design-2 resonators according to various embodiments.

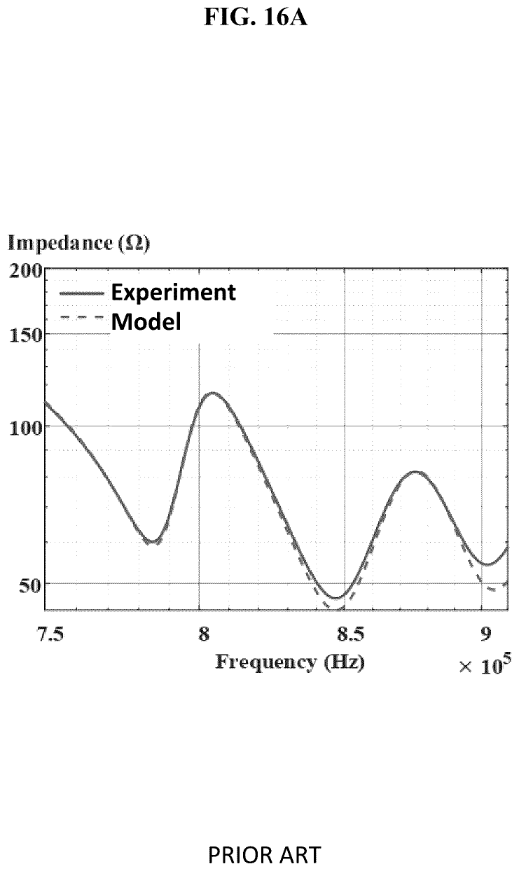

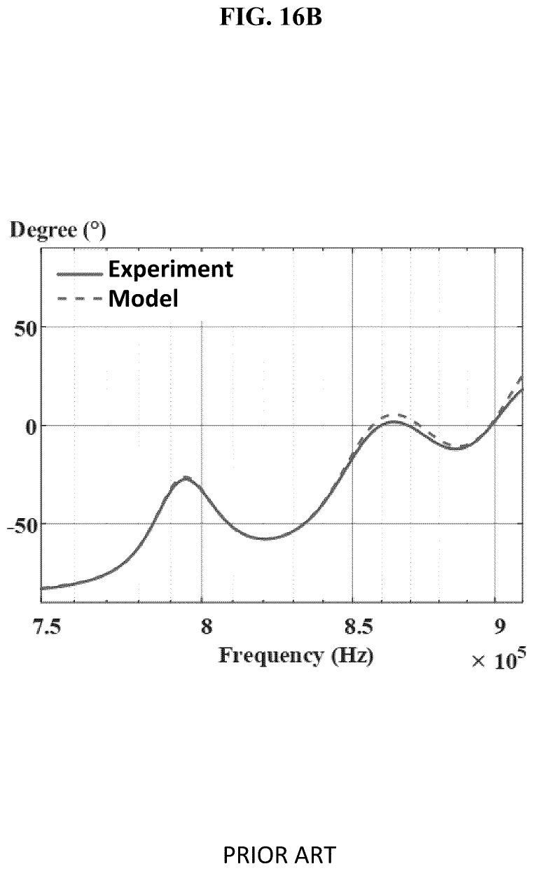

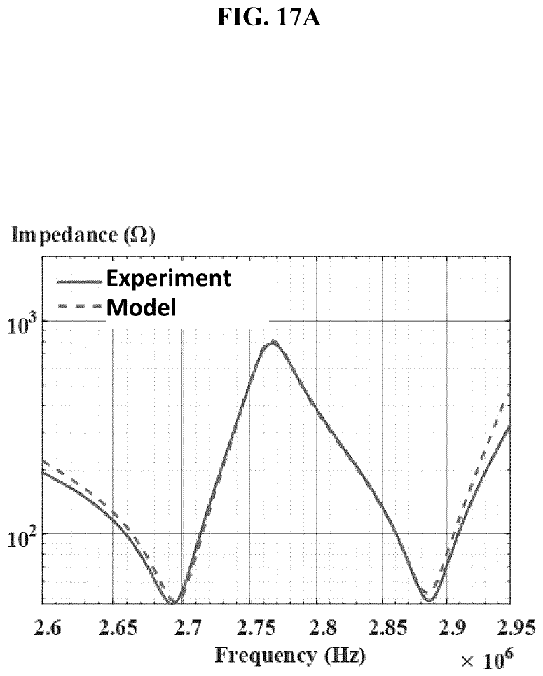

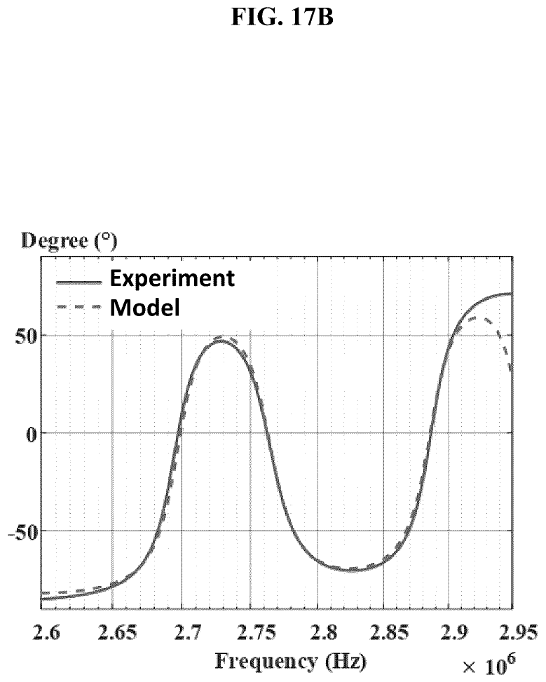

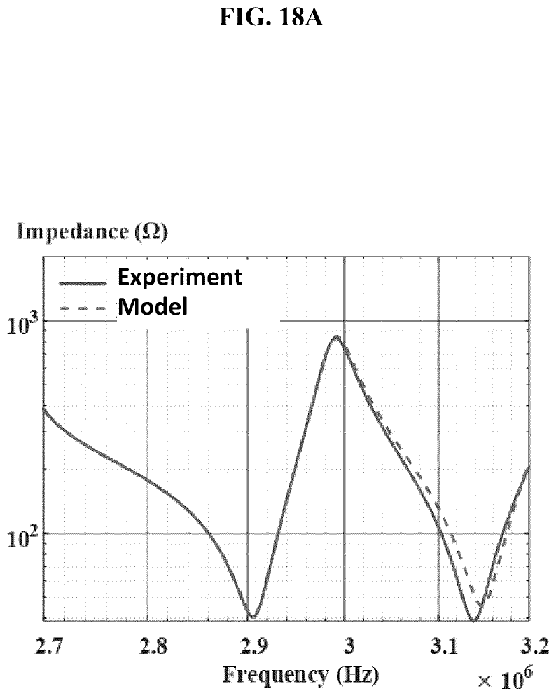

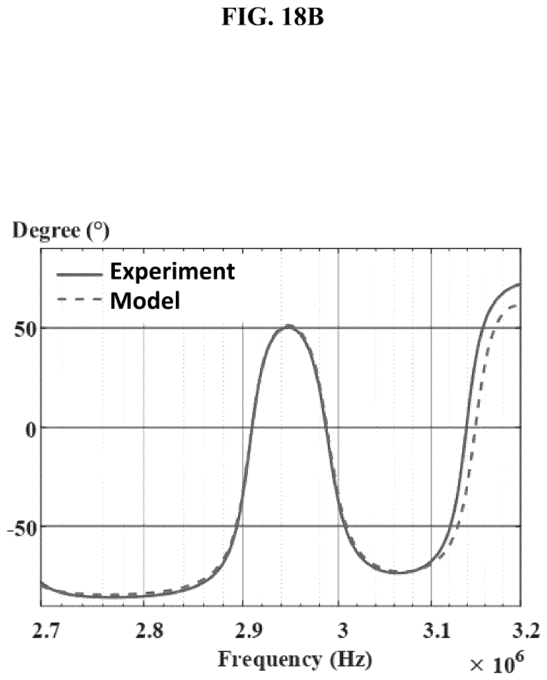

FIGS. 16A-B, FIGS. 17A-B and FIGS. 18A-B show the frequency spectra of the input of the 4-resonators domino WPT systems with conventional PCB resonators as well as Design-1 and Design-2 resonators, respectively. The impedance curves from the model are close to the experimental results. The accuracy of the model in frequency domain is verified.

FIG. 16A is a plot of impedance (in ohms or (2) as a function of frequency (in Hertz or Hz) illustrating the input impedance of the 4-resonators domino wireless power transfer (WPT) system of conventional printed circuit board (PCB) resonators. FIG. 16B is a plot of phase (in degrees or °) as a function of frequency (in Hertz or Hz) illustrating the phase response of the 4-resonators domino wireless power transfer (WPT) system of conventional printed circuit board (PCB) resonators. FIG. 17A is a plot of impedance (in ohms or (2) as a function of frequency (in Hertz or Hz) illustrating the input impedance of the 4-resonators domino wireless power transfer (WPT) system of Design-1 printed circuit board (PCB) resonators according to various embodiments. FIG. 17B is a plot of phase (in degrees or °) as a function of frequency (in Hertz or Hz) illustrating the phase response of the 4-resonators domino wireless power transfer (WPT) system of Design-1 printed circuit board (PCB) resonators according to various embodiments. FIG. 18A is a plot of impedance (in ohms or (2) as a function of frequency (in Hertz or Hz) illustrating the input impedance of the 4-resonators domino wireless power transfer (WPT) system of Design-2 printed circuit board (PCB) resonators according to various embodiments. FIG. 18B is a plot of phase (in degrees or °) as a function of frequency (in Hertz or Hz) illustrating the phase response of the 4-resonators domino wireless power transfer (WPT) system of Design-2 printed circuit board (PCB) resonators according to various embodiments.

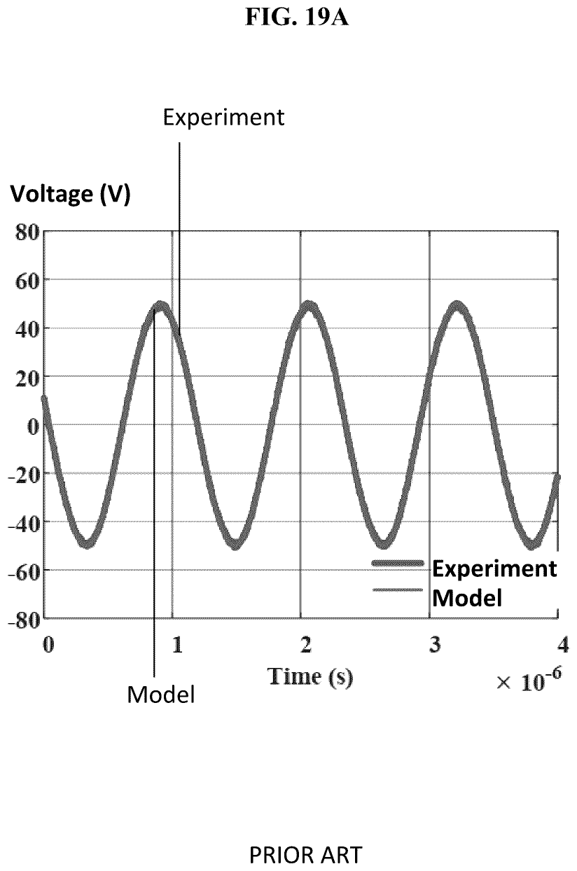

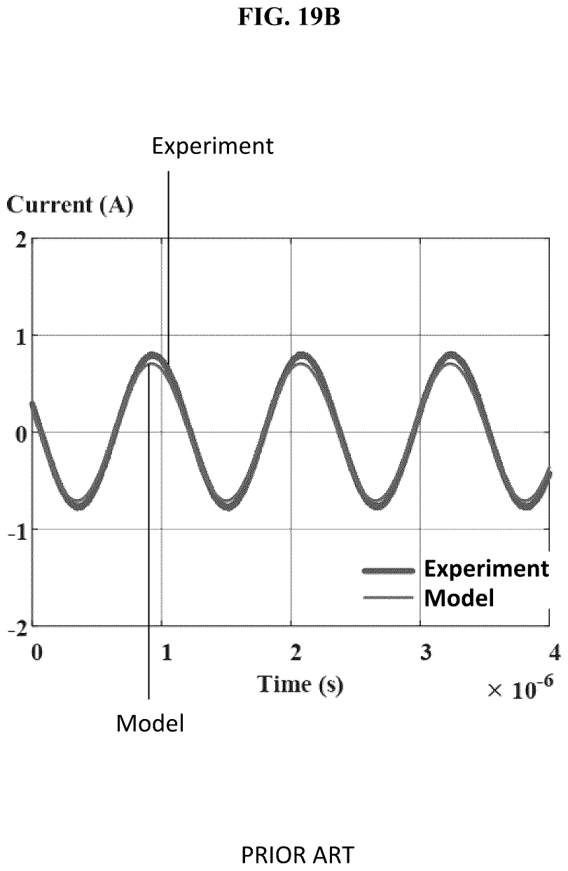

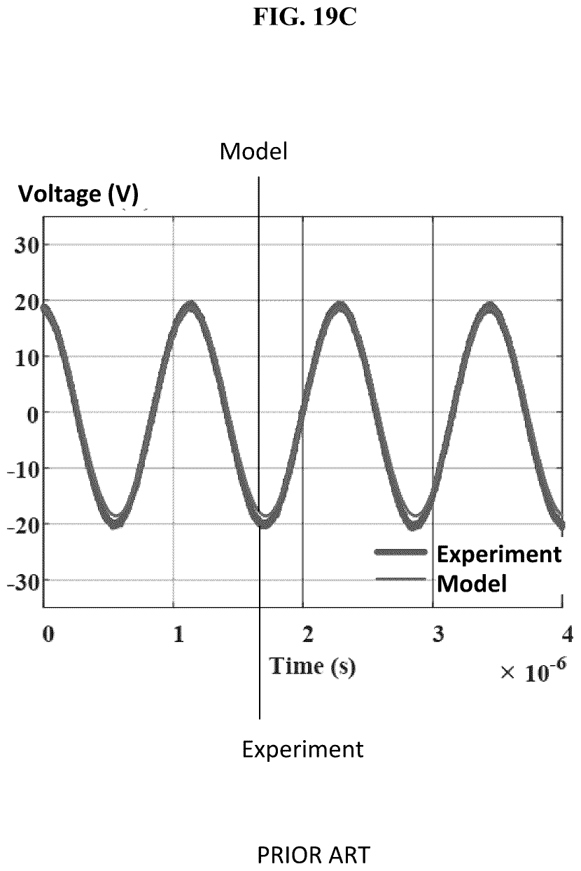

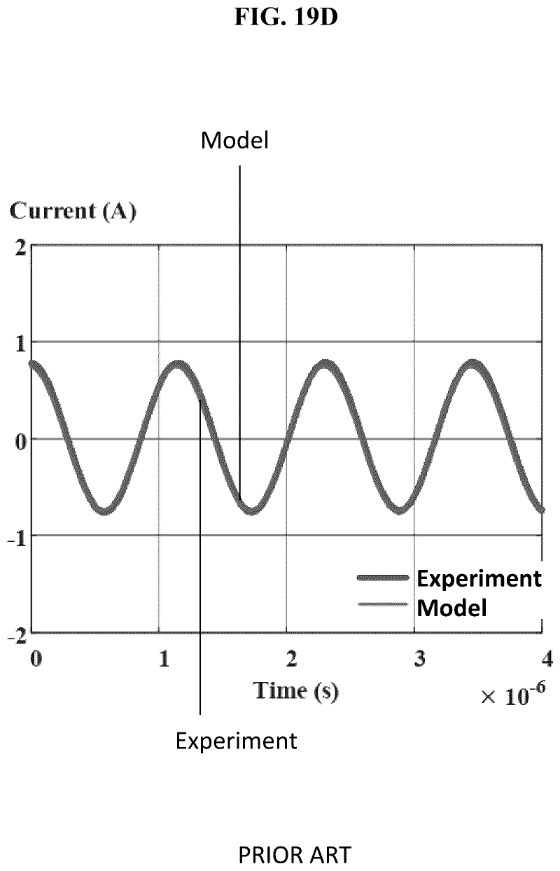

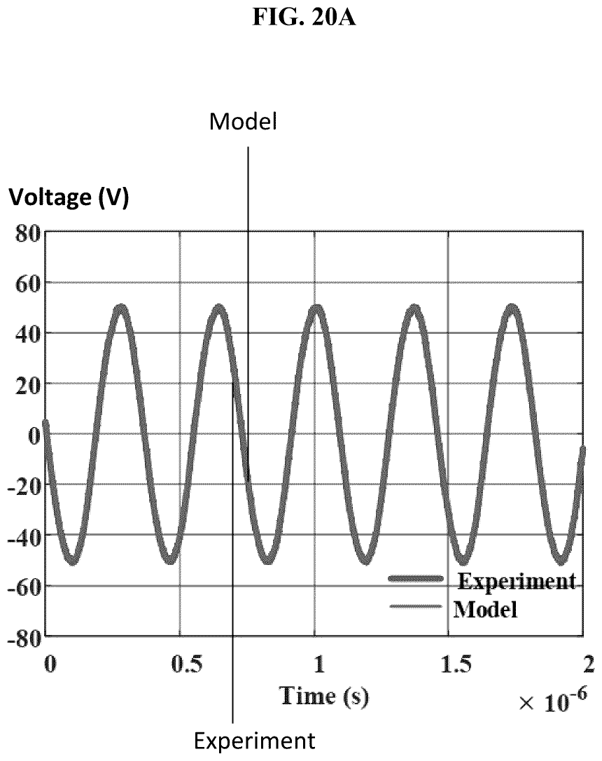

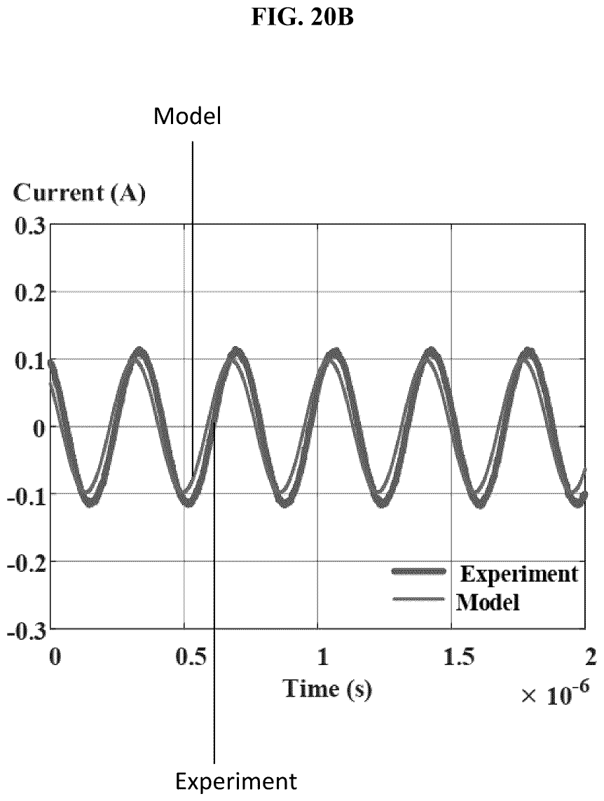

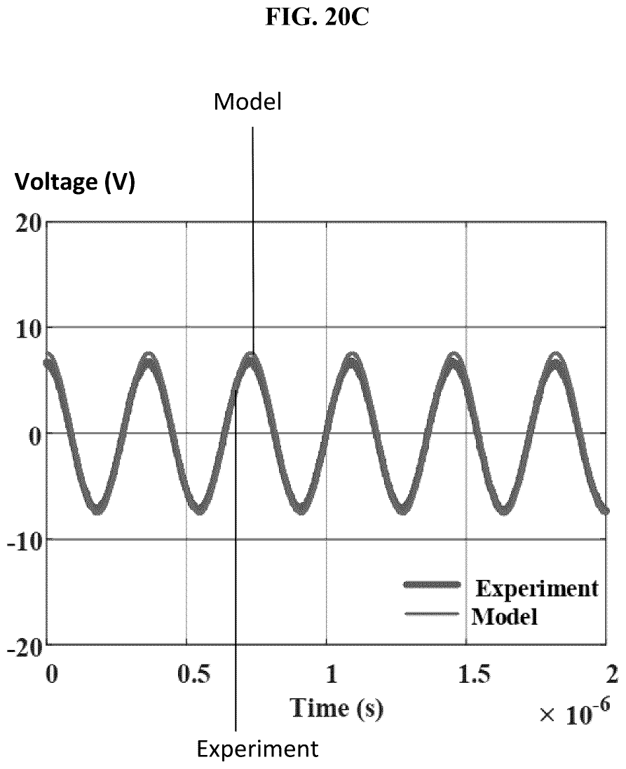

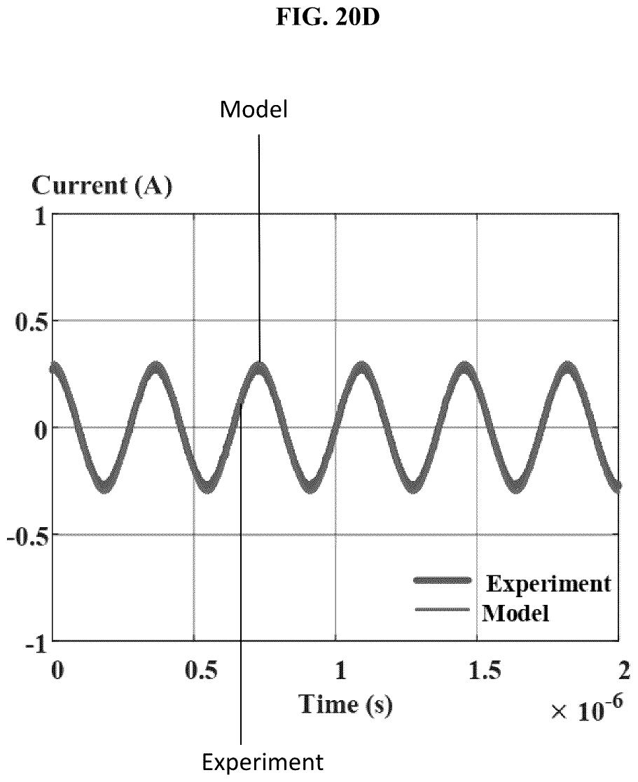

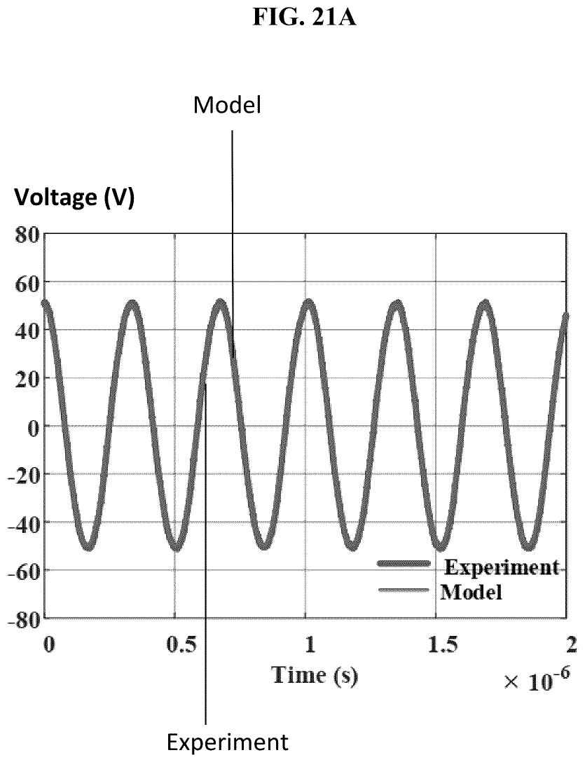

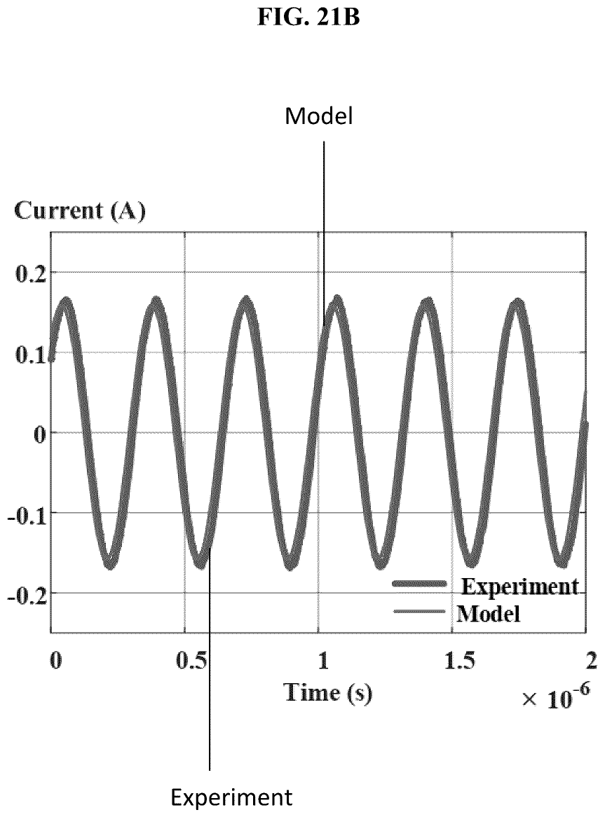

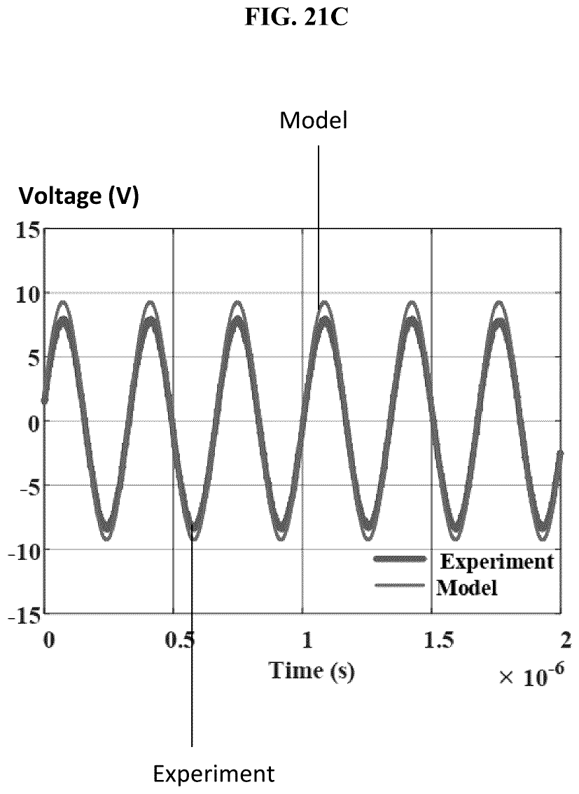

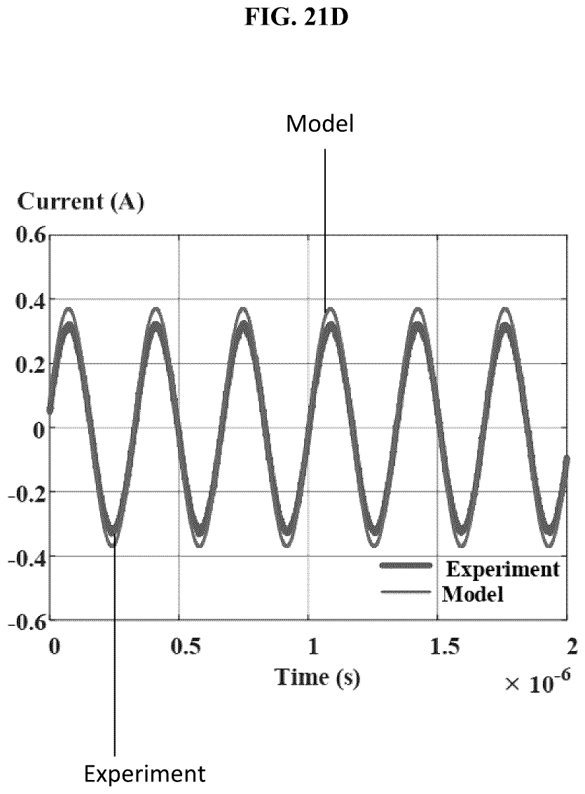

To further verify the accuracy of the model, time-domain tests are performed. The amplitude of the alternating current (AC) excitation is 50 V. The operating frequencies of these domino systems are 866 kHz, 2.75 MHz and 2.96 MHz, corresponding to the self-resonant frequencies of the PCB resonators (see FIG. 12). FIGS. 19A-D, FIGS. 20A-D and FIGS. 21A-D show the time-domain waveforms of the 4-resonators domino WPT systems with conventional design, design-1, and design-2 PCB resonators. The time domain waveforms from the model are very close to the experimental ones. The accuracy of the model in time domain has been verified.

FIG. 19A shows a plot of voltage (in volts or V) as a function of time (in seconds or s) illustrating the input voltage vᵢₙ waveform of the 4-resonators domino wireless power transfer (WPT) system of conventional printed circuit board (PCB) resonators. FIG. 19B shows a plot of current (in amperes or A) as a function of time (in seconds or s) illustrating the input current iᵢₙ waveform of the 4-resonators domino wireless power transfer (WPT) system of conventional printed circuit board (PCB) resonators. FIG. 19C shows a plot of voltage (in volts or V) as a function of time (in seconds or s) illustrating the output voltage vₒ waveform of the 4-resonators domino wireless power transfer (WPT) system of conventional printed circuit board (PCB) resonators. FIG. 19D shows a plot of current (in amperes or A) as a function of time (in seconds or s) illustrating the output current iₒ waveform of the 4-resonators domino wireless power transfer (WPT) system of conventional printed circuit board (PCB) resonators.

FIG. 20A shows a plot of voltage (in volts or V) as a function of time (in seconds or s) illustrating the input voltage vᵢₙ waveform of the 4-resonators domino wireless power transfer (WPT) system of Design-1 printed circuit board (PCB) resonators according to various embodiments. FIG. 20B shows a plot of current (in amperes or A) as a function of time (in seconds or s) illustrating the input current iᵢₙ waveform of the 4-resonators domino wireless power transfer (WPT) system of Design-1 printed circuit board (PCB) resonators according to various embodiments. FIG. 20C shows a plot of voltage (in volts or V) as a function of time (in seconds or s) illustrating the output voltage vₒ waveform of the 4-resonators domino wireless power transfer (WPT) system of Design-1 printed circuit board (PCB) resonators according to various embodiments. FIG. 20D shows a plot of current (in amperes or A) as a function of time (in seconds or s) illustrating the output current iₒ waveform of the 4-resonators domino wireless power transfer (WPT) system of Design-1 printed circuit board (PCB) resonators according to various embodiments.

FIG. 21A shows a plot of voltage (in volts or V) as a function of time (in seconds or s) illustrating the input voltage vᵢₙ waveform of the 4-resonators domino wireless power transfer (WPT) system of Design-2 printed circuit board (PCB) resonators according to various embodiments. FIG. 21B shows a plot of current (in amperes or A) as a function of time (in seconds or s) illustrating the input current iᵢₙ waveform of the 4-resonators domino wireless power transfer (WPT) system of Design-2 printed circuit board (PCB) resonators according to various embodiments. FIG. 21C shows a plot of voltage (in volts or V) as a function of time (in seconds or s) illustrating the output voltage vₒ waveform of the 4-resonators domino wireless power transfer (WPT) system of Design-2 printed circuit board (PCB) resonators according to various embodiments. FIG. 21D shows a plot of current (in amperes or A) as a function of time (in seconds or s) illustrating the output current iₒ waveform of the 4-resonators domino wireless power transfer (WPT) system of Design-2 printed circuit board (PCB) resonators according to various embodiments.

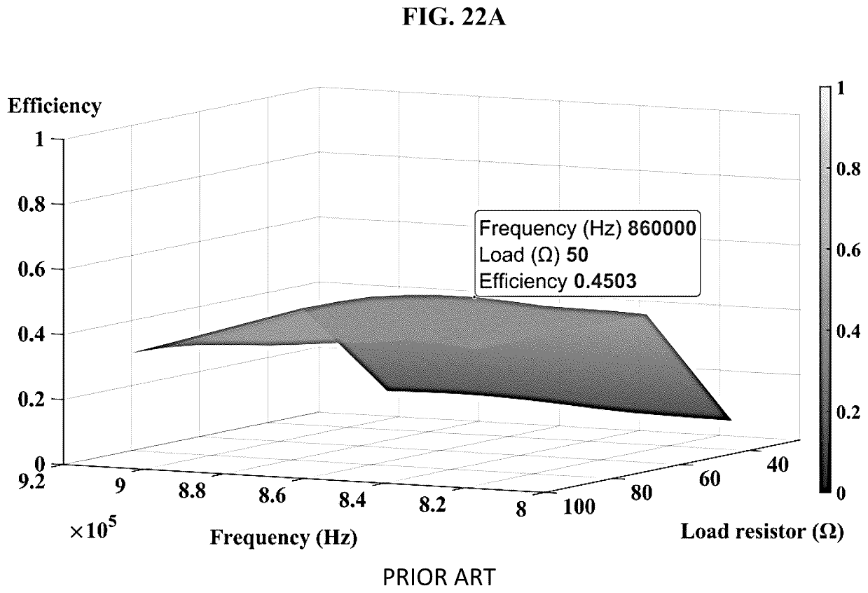

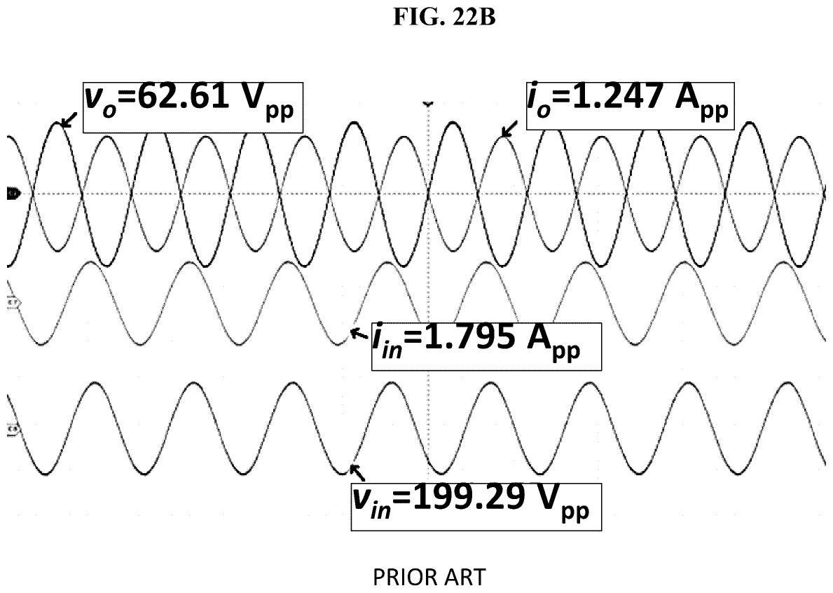

FIG. 22A is a plot of efficiency as a function of frequency (in Hertz or Hz) and load resistance (in ohms or (2) illustrating the efficiency curve of the 4-resonators domino wireless power transfer (WPT) system of conventional printed circuit board (PCB) resonators. It is shown in FIG. 22A that the efficiency of the domino system with conventional PCB resonators is 45.0% when the load is 50Ω and the operating frequency is 860 kHz. The time-domain waveforms of the domino system operating at maximum efficiency point are shown in FIG. 22B. FIG. 22B shows the time-domain waveforms of the 4-resonators domino wireless power transfer (WPT) system of conventional printed circuit board (PCB) resonators.

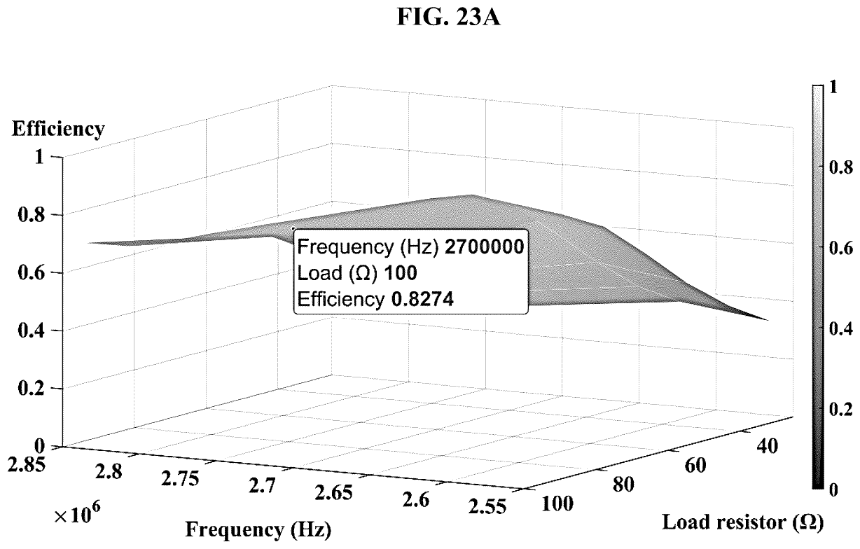

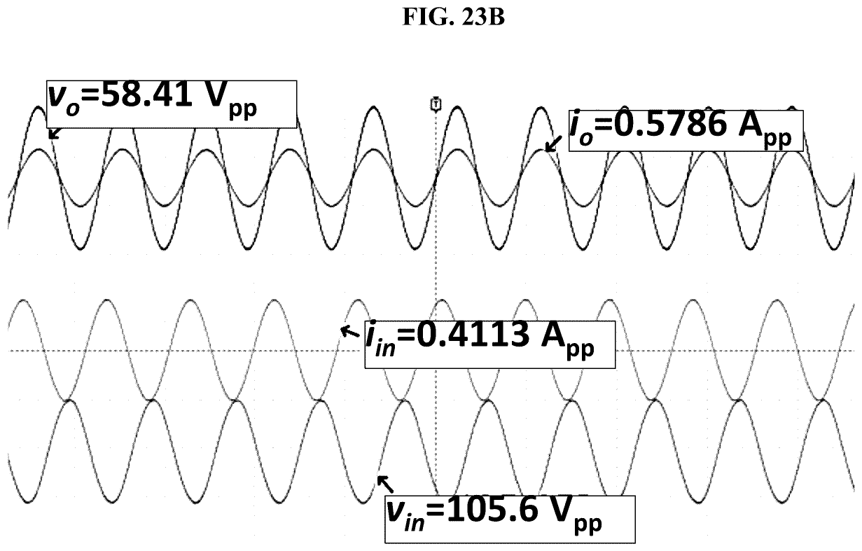

FIG. 23A is a plot of efficiency as a function of frequency (in Hertz or Hz) and load resistance (in ohms or Ω) illustrating the efficiency curve of the 4-resonators domino wireless power transfer (WPT) system of Design-1 printed circuit board (PCB) resonators according to various embodiments. It is shown in FIG. 23A that the efficiency of the domino system with Design-1 PCB resonators is 82.7% when the load is 100Ω and the operating frequency is 2700 kHz. The time-domain waveforms of the domino system operating at maximum efficiency point are shown in FIG. 23B. FIG. 23B shows the time-domain waveforms of the 4-resonators domino wireless power transfer (WPT) system of Design-1 printed circuit board (PCB) resonators according to various embodiments.

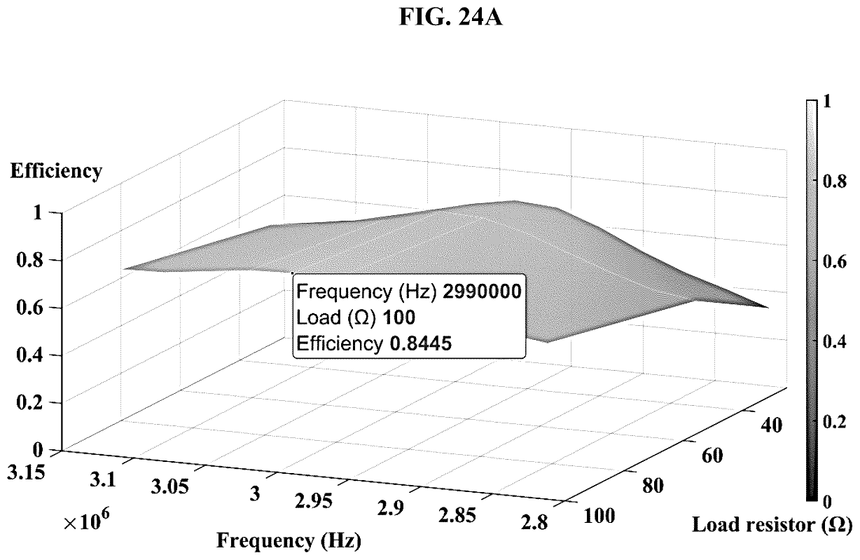

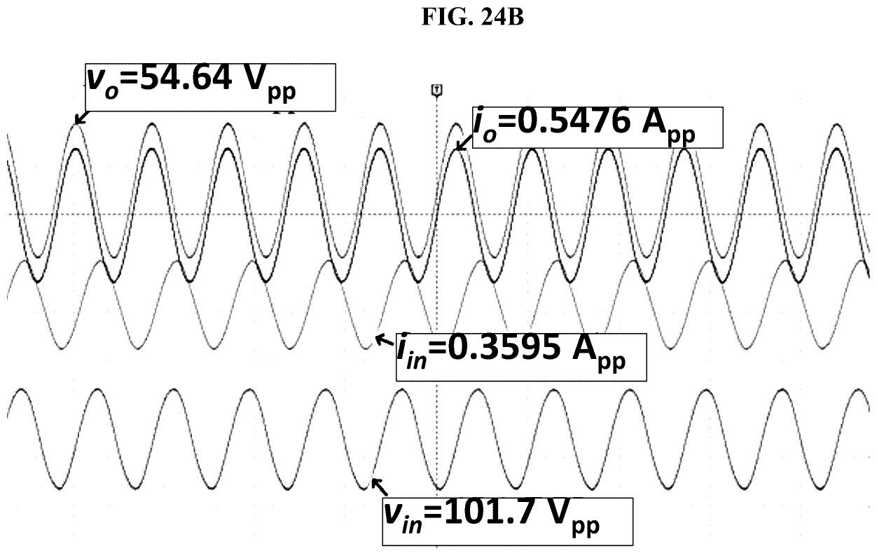

FIG. 24A is a plot of efficiency as a function of frequency (in Hertz or Hz) and load resistance (in ohms or (2) illustrating the efficiency curve of the 4-resonators domino wireless power transfer (WPT) system of Design-2 printed circuit board (PCB) resonators according to various embodiments. It is shown in FIG. 24A that the efficiency of the domino system with Design-2 PCB resonators is 84.5% when the load is 100Ω and the operating frequency is 2990 kHz. The time-domain waveforms of the domino system operating at maximum efficiency point are shown in FIG. 24B. FIG. 24B shows the time-domain waveforms of the 4-resonators domino wireless power transfer (WPT) system of Design-2 printed circuit board (PCB) resonators according to various embodiments.

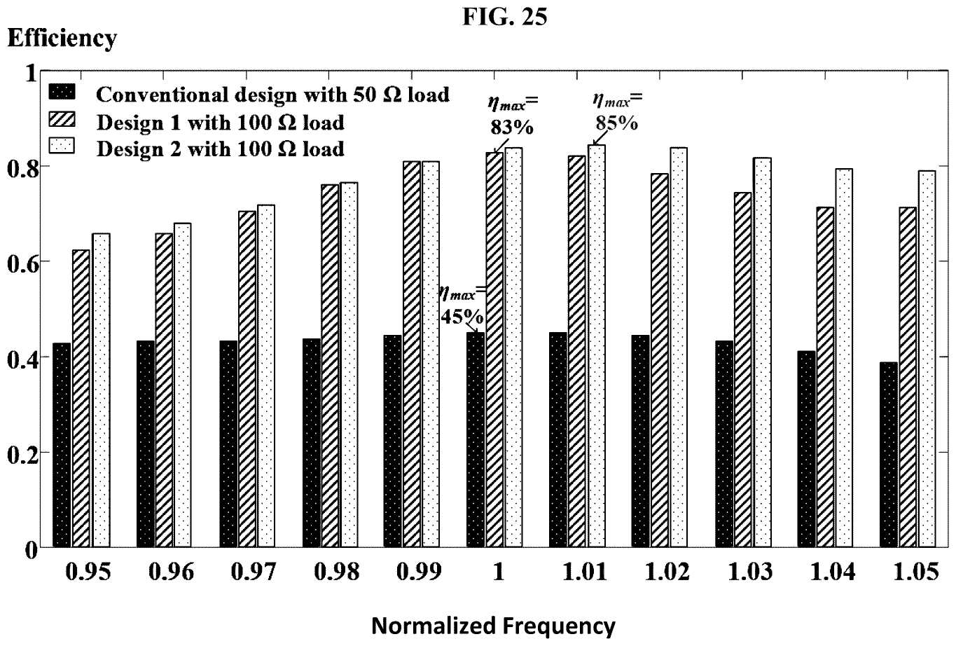

FIG. 25 is a plot of efficiency as a function of normalized frequency comparing the transmission efficiencies of the system with conventional printed circuit board (PCB) resonators, as well as the systems with Design-1 and Design-2 printed circuit board (PCB) resonators according to various embodiments.

Various embodiments may relate to PCB resonators based on two co-axially arranged PCBs separated by a small airgap to reduce interwinding capacitance. Various embodiments may relate to PCB resonator having air-trenches between adjacent turns to reduce intra-winding capacitance. An accurate distributed circuit model has been adopted to study the impedance and phase characteristics of a conventional resonator and two proposed resonators. The comparative study confirms that various embodiments may have significant improvements in the quality factor, resonant frequency, and transmission efficiency. Compared with the conventional resonator, various embodiments may increase the Q factor from 44 to 226, and the resonant frequency from 866 kHz to 2.96 MHz. In the same domino wireless power transfer system, the transmission efficiency may be increased from 45% to 85%.

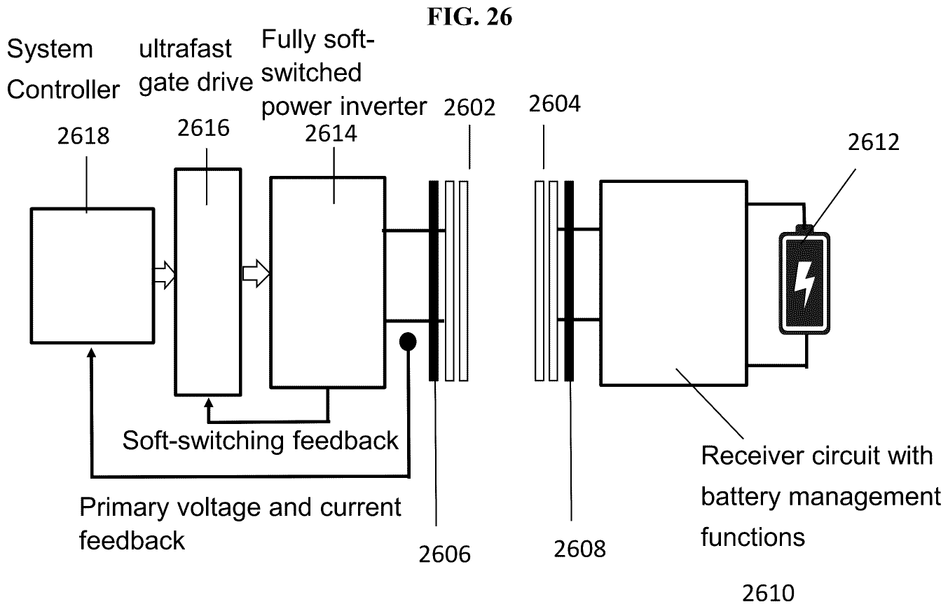

FIG. 26 shows a schematic of a wireless power transfer (WPT) system according to various embodiments. The WPT system may include a transmitter resonator 2602 and a receiver resonator 2604. In other words, the one or more printed circuit board (PCB) resonators may include a transmitter resonator 2602 and a receiver resonator 2604. Each of the resonators 2062, 2604 may include two printed PCBs as described herein. The WPT system may also include a first metasurface shield 2606 and a second metasurface shield 2608 such that the transmitter resonator 2602 and the receiver resonator 2604 are between the first metasurface shield 2606 and the second metasurface shield 2608. The metasurface shields 2606, 2608 may shield the resonators 2602, 2604 from external electromagnetic fields. There may not be any metasurface shield between the transmitter resonator 2602 and the receiver resonator 2604. The first metasurface shield may include a plurality of metasurface structures. Likewise, the second metasurface shield may include a plurality of metasurface structures. The metasurface structures may include one or more metals and/or one or more dielectric materials.

The WPT system may include a receiver circuit arrangement 2610 in electrical connection with the receiver resonator 2604. The receiver circuit arrangement 2610 may be configured to be connected to a battery 2612 for charging the battery 2612. The WPT system may also include a power inverter 2614 in electrical connection with the transmitter resonator 2602. The WPT system may also include a gate drive 2616 in electrical connection with the power inverter 2614. The WPT system may additionally include a system controller 2618 in electrical connection with the gate drive 2616. The system controller 2618 may be configured to control the gate drive 2616 to drive the power inverter 2614 such that electromagnetic fields are established between the transmitter resonator 2602 and the receiver resonator 2604 for power transfer. The power inverter 2614 may provide switching feedback to the gate drive 2616. The system controller 2618 may also be configured to receive primary voltage and current feedback. The metasurface shield 2606 may prevent the electromagnetic fields generated by the transmitter resonator 2602 and the receiver resonator 2604 from affecting the system controller 2618, the gate drive 2616 and the power inverter 2614. The metasurface shield 2608 may prevent the electromagnetic fields generated by the transmitter resonator 2602 and the receiver resonator 2604 from affecting the receiver circuit arrangement 2610. The metasurface shields 2606, 2608 may enclose and confine the electromagnetic field between the transmitter resonator 2602 and receiver resonator 2604 in order to minimize or reduce electromagnetic radiation outside the shielded resonator structure.

1. A printed circuit board (PCB) resonator comprising:
a first printed circuit board (PCB) comprising a first printed circuit board (PCB) substrate having only one side printed with a first coil; and
a second printed circuit board (PCB) spaced apart from the first printed circuit board (PCB), the second printed circuit board (PCB) comprising a second printed circuit board (PCB) substrate having only one side printed with a second coil;
wherein the first printed circuit board (PCB) substrate comprises slots between portions of the first printed circuit board (PCB) substrate in contact with the first coil; and
wherein the second printed circuit board (PCB) substrate comprises slots between portions of the second printed circuit board (PCB) substrate in contact with the second coil.

2. The printed circuit board (PCB) resonator according to claim 1, wherein the second printed circuit board (PCB) is spaced apart from the first printed circuit board (PCB) by an air gap.

3. The printed circuit board (PCB) resonator according to claim 1, wherein the second printed circuit board (PCB) is spaced apart from the first printed circuit board (PCB) by a sheet of non-conductive material with a dielectric constant and a loss tangent lower than that of a printed circuit board (PCB) material comprised in the first printed circuit board (PCB) substrate and the second printed circuit board (PCB) substrate.

4. The printed circuit board (PCB) resonator according to claim 1, wherein the first coil printed on the first printed circuit board (PCB) substrate and the second coil printed on the second printed circuit board (PCB) substrate face each other.

5. The printed circuit board (PCB) resonator according to claim 1, wherein the printed circuit board (PCB) resonator is devoid of a magnetic core.

6. The printed circuit board (PCB) resonator according to claim 1,
wherein the first coil surrounds a hollow space; and
wherein the second coil surrounds a hollow space.

7. The printed circuit board (PCB) resonator according to claim 1,
wherein the first coil comprises a first plurality of concentric turns; and
wherein the second coil comprises a second plurality of concentric turns.

8. The printed circuit board (PCB) resonator according to claim 7,
wherein trace widths of the first plurality of concentric turns are proportionally decreased from an outermost turn of the first plurality of concentric turns to an innermost turn of the first plurality of concentric turns; and
wherein trace widths of the second plurality of concentric turns are proportionally decreased from an outermost turn of the second plurality of concentric turns to an innermost turn of the second plurality of concentric turns.

9. The printed circuit board (PCB) resonator according to claim 7,
wherein the first plurality of concentric turns are spaced equally; and
wherein the second plurality of concentric turns are spaced equally.

10. The printed circuit board (PCB) resonator according to claim 1,
wherein the first coil comprises a single input-output terminal; and
wherein the second coil comprises a single input-output terminal.

11. The printed circuit board (PCB) resonator according to claim 10, further comprising:
a via electrically connecting the input-output terminal of the first coil and the input-output terminal of the second coil to form a parallel resonator.

12. The printed circuit board (PCB) resonator according to claim 10, wherein the printed circuit board (PCB) resonator is devoid of a via electrically connecting the input-output terminal of the first coil and the input-output terminal of the second coil, thereby forming a series resonator.

13. The printed circuit board (PCB) resonator according to claim 1, wherein the printed circuit board (PCB) resonator is configured to generate a magnetic field between the first coil and the second coil during operation.

14. The printed circuit board (PCB) resonator according to claim 1, wherein the printed circuit board (PCB) resonator is configured to generate electric fields within each of the first coil and the second coil and between the first coil and the second coil during operation.

15. The printed circuit board (PCB) resonator according to claim 1, wherein the printed circuit board (PCB) resonator is configured to operate at a predetermined resonant frequency, or within a range of +5% or −5% of the predetermined resonant frequency.

16. A wireless power transfer (WPT) system comprising one or more printed circuit board (PCB) resonators, each of the one or more printed circuit board (PCB) resonators comprising:
a first printed circuit board (PCB) comprising a first printed circuit board (PCB) substrate having only one side printed with a first coil; and
a second printed circuit board (PCB) spaced apart from the first printed circuit board (PCB), the second printed circuit board (PCB) comprising a second printed circuit board (PCB) substrate having only one side printed with a second coil;
wherein the first printed circuit board (PCB) substrate comprises slots between portions of the first printed circuit board (PCB) substrate in contact with the first coil; and
wherein the second printed circuit board (PCB) substrate comprises slots between portions of the second printed circuit board (PCB) substrate in contact with the second coil.

17. The wireless power transfer system according to claim 16,
wherein the one or more printed circuit board (PCB) resonators comprise a transmitter resonator and a receiver resonator; and
wherein the wireless power transfer system further comprises a first metasurface shield and a second metasurface shield such that the transmitter resonator and the receiver resonator are between the first metasurface shield and the second metasurface shield.

18. The wireless power transfer system according to claim 17, further comprising:
a receiver circuit arrangement in electrical connection with the receiver resonator;
a power inverter in electrical connection with the transmitter resonator;
a gate drive in electrical connection with the power inverter; and
a system controller in electrical connection with the gate drive.

19. A method of forming a printed circuit board (PCB) resonator, the method comprising:
forming a first printed circuit board (PCB) comprising a first printed circuit board (PCB) substrate having only one side printed with a first coil; and
forming a second printed circuit board (PCB) spaced apart from the first printed circuit board (PCB), the second printed circuit board (PCB) comprising a second printed circuit board (PCB) substrate having only one side printed with a second coil;
wherein the first printed circuit board (PCB) substrate comprises slots between portions of the first printed circuit board (PCB) substrate in contact with the first coil; and
wherein the second printed circuit board (PCB) substrate comprises slots between portions of the second printed circuit board (PCB) substrate in contact with the second coil.

20-33. (canceled)

34. A method of forming a wireless power transfer (WPT) system, the method comprising forming one or more printed circuit board (PCB) resonators, each of the one or more printed circuit board (PCB) resonators comprising:
a first printed circuit board (PCB) comprising a first printed circuit board (PCB) substrate having only one side printed with a first coil; and
a second printed circuit board (PCB) spaced apart from the first printed circuit board (PCB), the second printed circuit board (PCB) comprising a second printed circuit board (PCB) substrate having only one side printed with a second coil;
wherein the first printed circuit board (PCB) substrate comprises slots between portions of the first printed circuit board (PCB) substrate in contact with the first coil; and
wherein the second printed circuit board (PCB) substrate comprises slots between portions of the second printed circuit board (PCB) substrate in contact with the second coil.

35-36. (canceled)
